(19) United States
(12) Patent Application Publication
(10) Pub. No.: US 2025/0239508 A1
(43) Pub. Date: Jul. 24, 2025

(54) INTERPOSER SUBSTRATE WITH INTEGRATED STEP DIE CAVITY, AND RELATED INTEGRATED CIRCUIT (IC) PACKAGES AND FABRICATION METHODS

(71) Applicant: QUALCOMM Incorporated, San Diego, CA (US)

(72) Inventors: Seongryul Choi, Seongnam (KR); Kuiwon Kang, San Diego, CA (US); Hyun-Il Moon, Suwon-si (KR)

(21) Appl. No.: 18/605,021

(22) Filed: Mar. 14, 2024

Related U.S. Application Data
(60) Provisional application No. 63/622,604, filed on Jan. 19, 2024.

(51) Int. Cl. H01L 23/498; H01L 21/48; H01L 23/00; H01L 23/31

(52) U.S. Cl. CPC H01L 23/49822; H01L 21/4857; H01L 23/3128; H01L 23/49816; H01L 23/49838; H01L 24/16; H01L 2224/16227

(57) ABSTRACT

Interposer substrate with integrated step die cavity, and related integrated circuit (IC) packages and related fabrication methods. A die cavity integrated in an outer layer(s) of the interposer substrate provides room for a die to extend into the interposer substrate (e.g., to facilitate increased die height). Forming the die cavity in the outer layer(s) facilitates metal interconnects in an outer metallization layer of the interposer substrate being located adjacent to the die cavity can also enhance heat dissipation for the die extending into the die cavity. Forming the die cavity in the outer layer(s) of the interposer substrate also facilitates reduced distance between the interposer substrate and package substrate to facilitate reduced height vertical interconnects coupling the interposer substrate to the package substrate. This facilitates vertical interconnects with reduced aspect ratio and reduced pitch that can support dies with higher input/output (I/O) connection density.

### PRIORITY APPLICATION

The present application claims priority to U.S. Provisional Patent Application No. 63/622,604, filed Jan. 19, 2024 and entitled “INTERPOSER SUBSTRATE WITH INTEGRATED STEP DIE CAVITY, AND RELATED INTEGRATED CIRCUIT (IC) PACKAGES AND FABRICATION METHODS,” which is incorporated herein by reference in its entirety.

### BACKGROUND

### I. Field of the Disclosure

The field of the disclosure relates to interposer substrates that provide support and an electrical interface between multiple electrical devices, such as semiconductor dies, in an integrated circuit (IC) package.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a substrate as a routing substrate (e.g., a package substrate) to provide physical support and an electrical interface to the die(s). The die(s) is electrically interfaced to metal interconnects (e.g., metal traces) exposed in an upper layer of the substrate as part of signal routing paths. The substrate also includes one or more metallization layers that include metal interconnects (e.g., metal traces, metal lines) with vertical interconnect accesses (vias) coupling the metal interconnects together between adjacent metallization layers to provide electrical interfaces between the dies. If the substrate is a package substrate, the substrate also includes a lower, outer metallization layer that includes metal interconnects coupled to external metal interconnects (e.g., ball grid array (BGA) interconnects) to provide an external interface between the dies in the IC package. The external metal interconnects can also be coupled (e.g., soldered) to traces in a printed circuit board (PCB) to attach the package to the PCB and interface its die(s) with the circuitry of the PCB.

Some IC packages are known as multiple (multi-) die IC packages, which include multiple dies included in the IC package for different purposes or applications. For example, a multi-die IC package may include a first, application die (e.g., a processor or system-on-a-chip (SoC), and separate second die that provides supporting circuits for the application die. Splitting major applications/functions into separate dies is an alternative to putting circuits for all such applications/functions into a single die. Fabrication cost and complexity increase disproportionally with larger sized dies. For example, the second die may have a die with a power management circuit modem, a processor, or memory as examples. These multi-die IC packages can be provided in the form of a three-dimensional (3D) IC (3DIC) package. The 3DIC package can include a die package that includes a first die coupled to a first, bottom package substrate and encapsulated in a mold layer. The 3DIC can then include a second die that is coupled to the first die through an interposer substrate as part of a second die package. The interposer substrate is coupled to the die package and its mold layer. Vertical interconnects disposed in the mold layer of the die package and adjacent to the first die in a lateral/horizontal direction(s) connect metal interconnects in the interposer substrate to metal interconnects in the package substrate to provide signal routing paths between the second die and the first die through their respective interposer and package substrates.

As the number of input/output (I/O) pins of a die(s) to be provided in a 3DIC package increases, the pitch of vertical interconnects in the 3DIC package may need to decrease to support such higher number of I/O connections. Otherwise, the area of the 3DIC package may have to be increased, which may be undesirable. However, it may not be possible to reduce the pitch of the vertical interconnects using known or available fabrication methods given the aspect ratio of the vertical interconnects.

### SUMMARY OF THE DISCLOSURE

Aspects disclosed herein include an interposer substrate with integrated step die cavity. Related integrated circuit (IC) packages that include such an interposer substrate and related fabrication methods are also disclosed. The interposer substrate has one or more metallization layers to facilitate the interconnectivity of multiple electrical devices, such as semiconductor dies (“dies”). Each metallization layer in the interposer substrate has metal interconnects (e.g., metal lines, metal traces) insulated by an insulating layer, wherein the metal interconnects can provide signal routing paths in a first, horizontal direction in the interposer substrate. Vias are formed in the insulating layers to interconnect metal interconnects between vertically adjacent metallization layers to provide signal routing paths in a second, vertical direction. For example, the interposer substrate can be provided in a three-dimensional (3D) IC (3DIC) package to facilitate signal routing from a second, upper die coupled to the interposer substrate, to a lower package substrate in a die package to provide electrical coupling between the second die and a first die coupled to the package substrate. In such a 3DIC package, the first, lower die and vertical interconnects can be disposed in the mold layer of the die package and adjacent to the first die to provide signal routing paths between the interposer substrate and the package substrate and first die of the die package.

In exemplary aspects, a die cavity is integrated in at least a portion of an outer layer(s) of the interposer substrate that is configured to be coupled to a die package as part of an IC package. The die cavity provides room for a portion of a first die in a coupled die package as part of the IC package to extend partially into the die cavity in the second, vertical direction without necessarily having to increase the height of the mold layer of the die package. For example, the first die may have been increased in height and area to reduce hot spots of extreme temperatures. Also, by providing the die cavity in the outer layer(s) of the interposer substrate to receive a portion of a die, a remaining portion of the outer layer(s) of the interposer substrate that defines and remains outside of the die cavity in the first, horizontal direction(s) can extend further into a mold layer of a die package in the second, vertical direction without interfering with the die. This can reduce the vertical distance between the interposer substrate and the package substrate in the second, vertical direction where vertical connections are made to facilitate reduced aspect ratio vertical interconnects with a reduced pitch that can support dies with higher density input/output (I/O) connections. Thus, when the interposer substrate is included in a 3DIC package, vertical interconnections of reduced height and aspect ratio can be provided by a combination of first, reduced height vertical interconnects in the outer layer(s) coupled to second, reduced height vertical interconnects in the mold layer of the die package. This allows the vertical interconnections between the interposer substrate and the package substrate to be provided of a reduced pitch that can support higher I/O density dies.

In other exemplary aspects, the die cavity is formed by a removed portion of the outer layer(s) of the interposer substrate that will be adjacent to a die package when the interposer substrate is incorporated into an IC package. Removing a portion of the outer layer(s) of the interposer substrate forms a step die cavity. For example, an outer layer of the interposer substrate in which a portion is removed to form the die cavity can be a solder resist layer. Another outer layer of the interposer substrate in which a portion is removed to also form part of the die cavity can be an outer metallization layer of the interposer substrate in which the solder resist layer is formed. In either scenario, the metallization layout of the outer metallization layer of the interposer substrate can be designed and fabricated such that metal interconnects in the outer metallization layer are left residually adjacent to the die cavity after the portion of the outer layer(s) of the interposer substrate is removed to form the die cavity. In this manner, when the die cavity is formed in the outer layer(s) of the interposer substrate, these residual metal interconnects will still be present in the outer metallization layer of the interposer substrate adjacent to a die that extends into die cavity when the interposer substrate is incorporated into an IC package. The metal interconnects being adjacent to the die cavity and thermally coupled to a die extending into the die cavity provide heat dissipation from heat generated by the die through the metal interconnects and the interposer substrate. The metal interconnects in the outer metallization layer of the interposer substrate that are left residually adjacent to the die cavity can also be coupled to other metal interconnects in other metallization layers of the interposer substrate to provide additional efficient heat dissipation paths through the interposer substrate. Also, in other exemplary aspects, the portion of the outer layer(s) of the interposer substrate can be removed to form the die cavity such that the residual metal interconnects in the outer metallization layer of the interposer substrate are also exposed to the die cavity. This can enhance the thermal coupling between the metal interconnects in the interposer substrate and the die extending into the die cavity for improved heat dissipation, since there is no insulating material in the interposer substrate between the metal interconnects and the die cavity.

In another example, the die cavity is formed from by removing a portion of an outer layer(s) of the interposer substrate as including a portion of the solder resist layer of the interposer substrate and a portion of an outer metallization layer of the interposer substrate adjacent to the solder resist layer. If a portion of the outer metallization layer of the interposer substrate is also removed to form part of the die cavity, a step structure may also be present in the outer metallization layer adjacent to the die cavity. This is a result of removing a portion of the outer metallization layer of the interposer substrate to a given depth in the second, vertical direction thereby resulting in the outer metallization layer having a residual thinner portion adjacent to a thicker portion of the outer metallization layer which was not removed. This step structure could be susceptible to cracking as a result the thinner portion of the outer metallization layer having reduced strength and rigidness. However, the outer metallization layer in the interposer substrate is fabricated like or similar to the other metallization layers in the interposer substrate. Thus, there may be less disparity in the coefficient of thermal expansion (CTE) of the outer metallization layer and the other metallization layers in the interposer substrate. Thus, even with a step structure resulting from the formation of the thinner portion of the outer metallization layer to form part of the die cavity, the outer metallization layer may be less susceptible to cracking and risking delamination. For example, the outer metallization layer and the other metallization layers in the interposer substrate can be formed by the same fabrication process, and include a stronger, more rigid insulating layer material, such as pre-impregnated glass (PPG). This is opposed to, for example, forming the die cavity in a separate coating layer (e.g., a resin-coated copper (RCC) layer) that includes a coating material (e.g., resin) coated on metal posts plated to the outer metallization layer of the interposer substrate. The separate coating layer that may have a larger CTE and/or larger disparity in CTE from the metallization layers of the interposer substrate because of the coating layer having a larger CTE than the material used to form the insulating layers of the metallization layers of the interposer, including the outer metallization layer having the integrated die cavity.

In one example, the outer metallization layer can be processed when forming the die cavity such that the residual metal interconnects in the outer metallization layer adjacent to the die cavity are also directly exposed to the die cavity. In this manner, there is no insulating material present in the interposer substrate between an outer surface of the metal interconnects and the die cavity to improve thermal coupling of the die cavity to the metal interconnects in the outer metallization layer of the interposer substrate. The metal interconnects in the outer metallization layer can be exposed to the die cavity as a result of etching or otherwise removing a portion of the metal interconnects that will form part of and be adjacent to the die cavity such that an outer surface of the metal interconnects is exposed to the die cavity. Alternatively, the etching or otherwise removing a portion of the metal interconnects could also be performed by removing a portion of the insulating layer of the outer metallization layer in lieu of or along with portions of the metal interconnects as part of a single removal process (e.g. surface grinding) when forming the die cavity.

In other examples, the outer metallization layer of the interposer substrate can be designed to include metal interconnects adjacent to the die cavity in the form of a two-dimensional (2D) metal plate for enhanced thermal coupling to a die extending into the die cavity for heat dissipation. The metal plate could be present in the outer metallization layer that is not altered to form a part of the die cavity or could be a residual metal plate as a result of etching into a metal plate formed in an outer metallization layer of the interposer substrate. In another example, multiple metal interconnects that are not part of a single metal plate can be left residually in the outer metallization layer of the interposer substrate adjacent to the die cavity when the die cavity is formed in the outer layer(s) of the interposer substrate. In another example, multiple metal interconnects that are not part of a single metal plate can be left residually in the outer metallization layer of the interposer substrate adjacent to the die cavity when the die cavity is formed in the outer layer(s) of the interposer substrate, with such residual metal interconnects recessed from a bottom surface of the outer metallization layer. The form of the residual metal interconnects and/or metal plates in the outer layer(s) exposed to the die cavity as a result of forming the die cavity is based on the metal interconnect layout of the outer layer(s) in the area where the die cavity will be formed and the fabrication method used to form the die cavity in the outer layer(s).

In this regard, in one exemplary aspect, an interposer substrate is provided. The interposer substrate comprises a first metallization layer extending in a first direction. The first metallization layer comprises a plurality of first metal interconnects, and one or more second metal interconnects each comprising a first surface. The interposer substrate also comprises an outer layer adjacent to the first metallization layer in a second direction orthogonal to the first direction. The outer layer comprises an outer insulating layer comprising a plurality of outer metal interconnects each coupled to a first metal interconnect of the plurality of first metal interconnects. The interposer substrate also comprises a die cavity in at least a portion of the outer insulating layer adjacent to a first surface of each of the one or more second metal interconnects in the second direction.

In another exemplary aspect, a method of fabricating an interposer substrate for an IC package is provided. The method comprises forming a first metallization layer extending in a first direction, comprising: forming a plurality of first metal interconnects; and forming one or more second metal interconnects each comprising a first surface. The method also comprises forming an outer layer adjacent to the first metallization layer in a second direction orthogonal to the first direction, comprising: forming an outer insulating layer comprising a plurality of outer metal interconnects each coupled to a first metal interconnect of the plurality of first metal interconnects. The method also comprises forming a die cavity in at least a portion of the outer insulating layer adjacent to a first surface of each of the one or more second metal interconnects in the second direction.

In another exemplary aspect, an IC package is provided. The IC package comprises a die package, comprising: a package substrate comprising a plurality of fourth metal interconnects; a first die coupled to the package substrate; and a plurality of vertical interconnects each coupled to a fourth metal interconnect of the plurality of fourth metal interconnects. The IC package also comprises an interposer substrate coupled to the die package in a second direction orthogonal to a first direction. The interposer substrate comprises a first metallization layer extending in the first direction, the first metallization layer comprising: a plurality of first metal interconnects, and one or more second metal interconnects each comprising a first surface. The interposer substrate also comprises an outer layer coupled to the die package and between the die package and the first metallization layer in the second direction. The outer layer comprises an outer insulating layer comprising a plurality of outer metal interconnects each coupled to a first metal interconnect of the plurality of first metal interconnects and a vertical interconnect of the plurality of vertical interconnects. The interposer substrate also comprises a die cavity in at least a portion of the outer insulating layer adjacent to a first surface of each of the one or more second metal interconnects in the second direction. The first die is at least partially disposed in the die cavity in the second direction.

### BRIEF DESCRIPTION OF THE FIGURES

FIGS. 1A and 1B are side views of an exemplary integrated circuit (IC) package that includes an interposer substrate coupled to a die package that includes a first, lower die coupled to a package substrate, wherein an outer layer(s) of the interposer substrate adjacent to the first die includes an integrated die cavity;

FIGS. 2A-1 and 2A-2 are a respective side view and close-up partial side view of an exemplary interposer substrate in the form of an embedded trace substrate (ETS) interposer substrate with an integrated die cavity and that can be provided as the interposer substrate in the IC package in FIGS. 1A and 1B, wherein the outer ETS metallization layer has a metal plate exposed to the die cavity to facilitate enhanced thermal coupling to a die extending into the die cavity;

FIG. 2B is a side view of another exemplary interposer substrate in the form of an ETS interposer substrate with an integrated die cavity and that can be provided as the interposer substrate in the IC package in FIGS. 1A and 1B, wherein the outer ETS metallization layer has metal interconnects exposed to the die cavity to facilitate enhanced thermal coupling to a die extending into the die cavity;

FIG. 2C is a side view of another exemplary interposer substrate in the form of an ETS interposer substrate with an integrated die cavity and that can be provided as the interposer substrate in the IC package in FIGS. 1A and 1B, wherein the outer ETS metallization layer has recessed metal interconnects exposed to the die cavity to facilitate enhanced thermal coupling to a die extending into the die cavity;

FIGS. 3A and 3B are side views of another exemplary IC package that includes an interposer substrate in the form of a coreless modified semi-additive process (mSAP) interposer substrate coupled to a die package that includes a first, lower die coupled to a package substrate, wherein an outer layer(s) of the coreless mSAP interposer substrate adjacent to the first die includes an integrated die cavity;

FIG. 4A is a side view of another exemplary interposer substrate in the form of a coreless mSAP interposer substrate with an integrated die cavity and that can be provided as the interposer substrate in the IC package in FIGS. 3A and 3B, wherein the outer mSAP metallization layer has a metal plate exposed to the die cavity to facilitate enhanced thermal coupling to a die extending into the die cavity;

FIG. 4B is a side view of another exemplary interposer substrate in the form of a coreless mSAP interposer substrate with an integrated die cavity and that can be provided as the interposer substrate in the IC package in FIGS. 3A and 3B, wherein the outer mSAP metallization layer has metal interconnects exposed to the die cavity to facilitate enhanced thermal coupling to a die extending into the die cavity;

FIG. 4C is a side view of another exemplary interposer substrate in the form of a coreless mSAP interposer substrate with an integrated die cavity and that can be provided as the interposer substrate in the IC package in FIGS. 3A and 3B, wherein the outer mSAP metallization layer has recessed metal interconnects exposed to the die cavity to facilitate enhanced thermal coupling to a die extending into the die cavity;

FIGS. 5A and 5B are side views of another exemplary IC package that includes an interposer substrate in the form of a cored mSAP interposer substrate coupled to a die package that includes a first, lower die coupled to a package substrate, wherein an outer layer(s) of the cored mSAP interposer substrate adjacent to the first die includes an integrated die cavity;

FIG. 6A is a side view of another exemplary interposer substrate in the form of a cored mSAP interposer substrate with an integrated die cavity and that can be provided as the interposer substrate in the IC package in FIGS. 5A and 5B, wherein the outer mSAP metallization layer has a metal plate exposed to the die cavity to facilitate enhanced thermal coupling to a die extending into the die cavity;

FIG. 6B is a side view of another exemplary interposer substrate in the form of a cored mSAP interposer substrate with an integrated die cavity and that can be provided as the interposer substrate in the IC package in FIGS. 5A and 5B, wherein the outer mSAP metallization layer has metal interconnects exposed to the die cavity to facilitate enhanced thermal coupling to a die extending into the die cavity;

FIG. 6C is a side view of another exemplary interposer substrate in the form of a cored mSAP interposer substrate with an integrated die cavity and that can be provided as the interposer substrate in the IC package in FIGS. 5A and 5B, wherein the outer mSAP metallization layer has recessed metal interconnects exposed to the die cavity to facilitate enhanced thermal coupling to a die extending into the die cavity;

FIG. 7 is a flowchart illustrating an exemplary process of fabricating an interposer substrate that can be coupled to a die package, wherein an outer layer(s) of the interposer substrate includes an integrated die cavity, including, but not limited to, the interposer substrates in FIGS. 1A-6C;

FIGS. 8A-8D is a flowchart illustrating an exemplary fabrication process of fabricating the interposer substrate in FIGS. 1A-2C;

FIGS. 9A-9I-3 are exemplary fabrication stages during fabrication of the interposer substrate according to the exemplary fabrication process in FIGS. 8A-8D;

FIGS. 10A and 10B is a flowchart illustrating an exemplary process of fabricating an IC package that includes an interposer substrate, wherein an outer layer(s) of the interposer substrate includes an integrated die cavity, including, but not limited to, the interposer substrates in FIGS. 1A-6C, and including, but not limited to, the interposer substrates in FIGS. 1A-6C and 9I-3 and the IC packages in FIGS. 1A-1B, 3A-3B, and 5A-5B;

FIGS. 11A-11D are exemplary fabrication stages during fabrication of the IC package according to the exemplary fabrication process in FIGS. 10A-10B;

FIG. 12 is a block diagram of an exemplary wireless communications device that includes one or more IC packages that includes an interposer substrate, wherein an outer layer(s) of the interposer substrate includes an integrated die cavity, including, but not limited to, the interposer substrates in FIGS. 1A-6C, 9I-1-9I-3, and 11D and the IC packages in FIGS. 1A-1B, 3A-3B, 5A-5B, and 11D and that can be fabricated according to a fabrication process, including, but not limited to, the exemplary fabrication processes in FIGS. 7, 8A-8D, and 10A-10B; and

FIG. 13 is a block diagram of an exemplary electronic device in the form of a processor-based system that includes one or more IC packages that includes an interposer substrate, wherein an outer layer(s) of the interposer substrate includes an integrated die cavity, including but not limited to, the interposer substrates in FIGS. 1A-6C, 9I-1-9I-3, and 11D and the IC packages in FIGS. 1A-1B, 3A-3B, 5A-5B, and 11D and that can be fabricated according to a fabrication process, including, but not limited to, the exemplary fabrication processes in FIGS. 7, 8A-8D, and 10A-10B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include an interposer substrate with integrated step die cavity. Related integrated circuit (IC) packages that include such an interposer substrate and related fabrication methods are also disclosed. The interposer substrate has one or more metallization layers to facilitate the interconnectivity of multiple electrical devices, such as semiconductor dies (“dies”). Each metallization layer in the interposer substrate has metal interconnects (e.g., metal lines, metal traces) insulated by an insulating layer, wherein the metal interconnects can provide signal routing paths in a first, horizontal direction in the interposer substrate. Vias are formed in the insulating layers to interconnect metal interconnects between vertically adjacent metallization layers to provide signal routing paths in a second, vertical direction. For example, the interposer substrate can be provided in a three-dimensional (3D) IC (3DIC) package to facilitate signal routing from a second, upper die coupled to the interposer substrate, to a lower package substrate in a die package to provide electrical coupling between the second die and a first die coupled to the package substrate. In such a 3DIC package, the first, lower die and vertical interconnects can be disposed in the mold layer of the die package and adjacent to the first die to provide signal routing paths between the interposer substrate and the package substrate and first die of the die package.

In exemplary aspects, a die cavity is integrated in at least a portion of an outer layer(s) of the interposer substrate that is configured to be coupled to a die package as part of an IC package. The die cavity provides room for a portion of a first die in a coupled die package as part of the IC package to extend partially into the die cavity in the second, vertical direction without necessarily having to increase the height of the mold layer of the die package. For example, the first die may have been increased in height and area to reduce hot spots of extreme temperatures. Also, by providing the die cavity in the outer layer(s) of the interposer substrate to receive a portion of a die, a remaining portion of the outer layer(s) of the interposer substrate that defines and remains outside of the die cavity in the first, horizontal direction(s) can extend further into a mold layer of a die package in the second, vertical direction without interfering with the die. This can reduce the vertical distance between the interposer substrate and the package substrate in the second, vertical direction where vertical connections are made to facilitate reduced aspect ratio vertical interconnects with a reduced pitch that can support dies with higher density input/output (I/O) connections. Thus, when the interposer substrate is included in a 3DIC package, vertical interconnections of reduced height and aspect ratio can be provided by a combination of first, reduced height vertical interconnects in the outer layer(s) coupled to second, reduced height vertical interconnects in the mold layer of the die package. This allows the vertical interconnections between the interposer substrate and the package substrate to be provided of a reduced pitch that can support higher I/O density dies.

In other exemplary aspects, the die cavity is formed by a removed portion of the outer layer(s) of the interposer substrate that will be adjacent to a die package when the interposer substrate is incorporated into an IC package. Removing a portion of the outer layer(s) of the interposer substrate forms a step die cavity. For example, an outer layer of the interposer substrate in which a portion is removed to form the die cavity can be a solder resist layer. Another outer layer of the interposer substrate in which a portion is removed to also form part of the die cavity can be an outer metallization layer of the interposer substrate in which the solder resist layer is formed. In either scenario, the metallization layout of the outer metallization layer of the interposer substrate can be designed and fabricated such that metal interconnects in the outer metallization layer are left residually adjacent to the die cavity after the portion of the outer layer(s) of the interposer substrate is removed to form the die cavity. In this manner, when the die cavity is formed in the outer layer(s) of the interposer substrate, these residual metal interconnects will still be present in the outer metallization layer of the interposer substrate adjacent to a die that extends into die cavity when the interposer substrate is incorporated into an IC package. The metal interconnects being adjacent to the die cavity and thermally coupled to a die extending into the die cavity provide heat dissipation from heat generated by the die through the metal interconnects and the interposer substrate. The metal interconnects in the outer metallization layer of the interposer substrate that are left residually adjacent to the die cavity can also be coupled to other metal interconnects in other metallization layers of the interposer substrate to provide additional efficient heat dissipation paths through the interposer substrate. Also, in other exemplary aspects, the portion of the outer layer(s) of the interposer substrate can be removed to form the die cavity such that the residual metal interconnects in the outer metallization layer of the interposer substrate are also exposed to the die cavity. This can enhance the thermal coupling between the metal interconnects in the interposer substrate and the die extending into the die cavity for improved heat dissipation, since there is no insulating material in the interposer substrate between the metal interconnects and the die cavity.

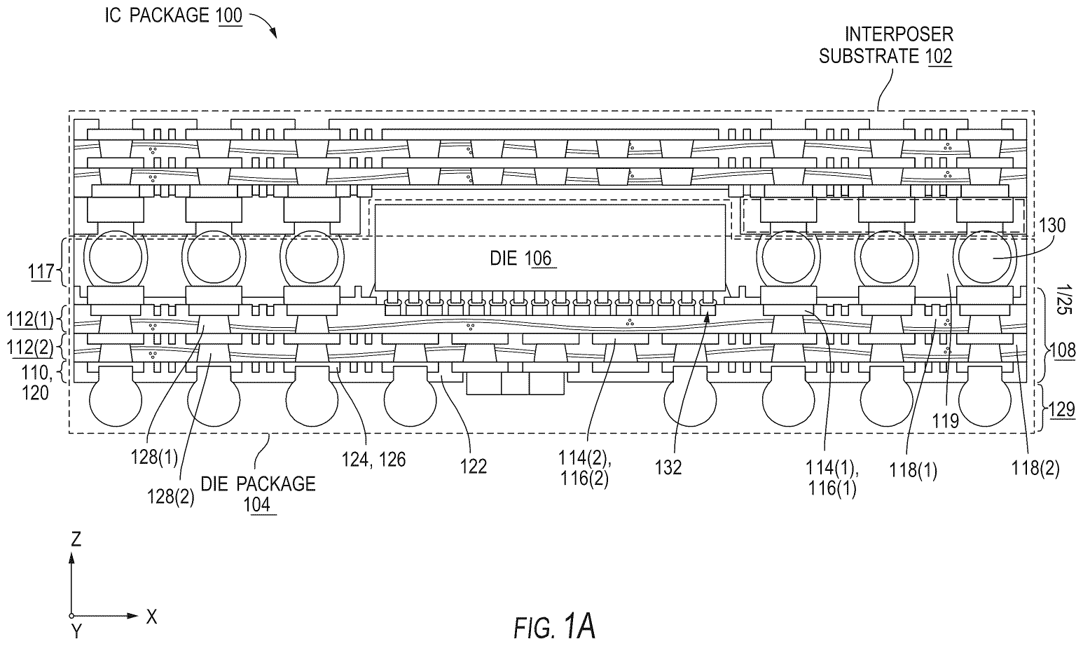

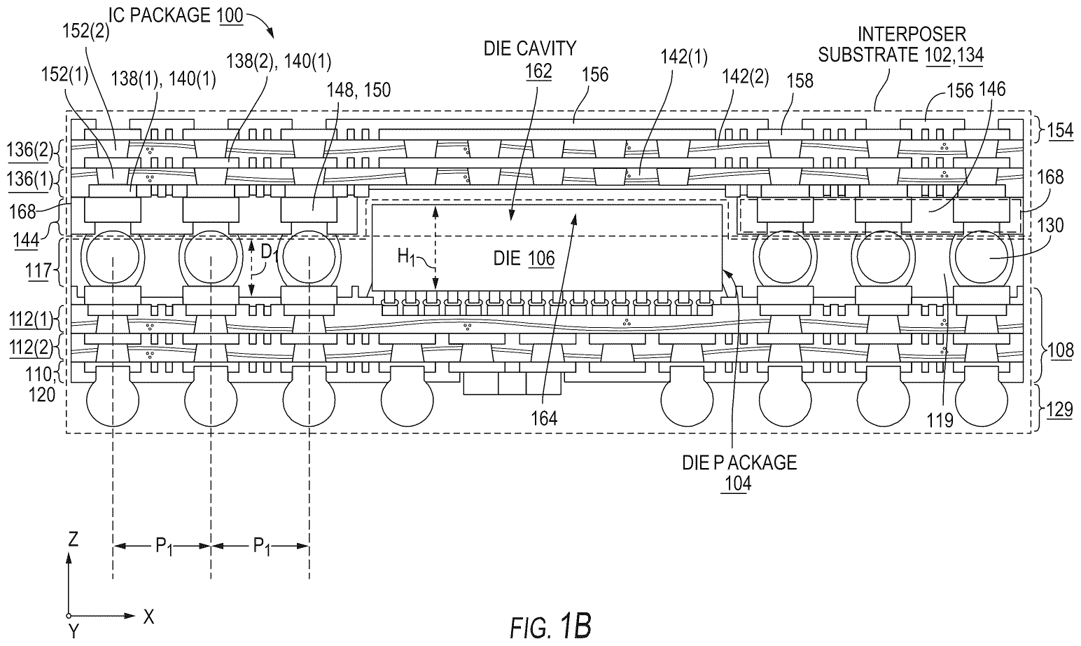

In this regard, FIGS. 1A and 1B are side views of an exemplary integrated circuit (IC) package 100 that includes an interposer substrate 102 coupled to a die package 104. As shown in FIG. 1A, the die package 104 includes a first, lower die 106 coupled to a package substrate 108. In this example, the package substrate 108 is an embedded trace substrate (ETS) substrate 108 meaning that one or more of its metallization layers 112(1), 112(2) (also referred to as ETS metallization layers 112(1), 112(2)) include respective metal interconnects 114(1), 114(2) in the form of metal traces 116(1), 116(2) embedded in a respective insulating layer 118(1), 118(2). The metallization layers 112(1), 112(2) extend in a first, horizontal direction (X-axis and Y-axis directions). The metal traces 116(1), 116(2) can be formed to facilitate both horizontal routing in the first, horizontal direction (X-axis and/or Y-axis directions) and vertical routing in the second, vertical direction (Z-axis direction). The die package 104 includes a mold layer 117 of a mold material 119 that is disposed on the package substrate 108 and around and adjacent to the first die 106 to insulate vertical interconnects 130 (e.g., metal balls such as copper balls or solder balls) and die interconnects 132 of the first die 106 as well as provide stability to the first die 106.

In this example, as shown in FIG. 1A, the package substrate 108 of the die package 104 also includes an outer layer 110 that is an outer, solder resist layer 120 in this example. An outer layer, including the outer layer 110, is a layer that forms an exterior side of the component device, which in this case is the package substrate 108. The outer, solder resist layer 120 is adjacent to the second metallization layer 112(2) in the second, vertical direction (Z-axis direction). The outer, solder resist layer 120 includes an outer insulating layer 122 with metal interconnects 124 in the form of metal posts 126 (as a form of metal interconnects (e.g., copper posts)) exposed to allow external metal interconnects 129 (e.g., solder balls) to be coupled to the metal posts 126 for external signal routing. The ETS package substrate 108 may be considered a three (3) layer (3L) substrate with its two (2) metallization layers 112(1), 112(2) and the solder resist layer 120. However, such is not limiting, and the package substrate 108 could have less than or more than three (3) layers (e.g., a two layer (2L) package substrate or four layer (4L) package substrate). The metal posts 126 are formed on and coupled to vias 128(2) in the second metallization layer 112(2) in this example, which can in turn be coupled to metal traces 116(2), which can be coupled to vias 128(1) and metal traces 116(1) in the first metallization layer 112(1) to provide signal routing in the package substrate 108. In this example, signal routing is provided from the external metal interconnects 129 through the package substrate 108 and to the vertical interconnects 130 (e.g., solder balls, ball grid array (BGA) interconnects) that are coupled to the interposer substrate 102. The die interconnects 132 of the first die 106 are also coupled to the first metallization layer 112(1) of the package substrate 108 to provide signal routing to the first die 106, which can be from the external metal interconnects 129 or the interposer substrate 102 through the vertical interconnects 130.

With reference to the IC package 100 as shown in FIG. 1B, the interposer substrate 102 in this example is also an ETS interposer substrate 134 meaning that one or more of its metallization layers 136(1), 136(2) (also referred to as ETS metallization layers 136(1) 136(2)) include respective metal interconnects 138(1), 138(2) in the form of metal traces 140(1), 140(2) embedded in a respective insulating layer 142(1), 142(2). Note that the first metallization layer 136(1) is an outer layer/outer metallization layer with respect to the metallization layers 136(1), 136(2) in that the first metallization layer 136(1) forms an exterior side of the metallization layers 136(1), 136(2). The metallization layers 136(1), 136(2) extend in the first, horizontal direction (X-axis and Y-axis directions). The metal traces 140(1), 140(2) can be formed to facilitate both horizontal routing in the first, horizontal direction (X-axis and/or Y-axis directions) and vertical routing in the second, vertical direction (Z-axis direction).

Note that in this example, the insulating layers 142(1), 142(2) of the interposer substrate 102 are made of an organic material, such as an organic substrate. The respective metal interconnects 138(1), 138(2) are formed in the respective insulating layers 142(1), 142(2) therein as embedded metal interconnects 138(1), 138(2). An organic material can be composed of carbon-based compounds, which may be lightweight and less cost. An organic material may also be easier to manufacture and process due to the nature of its organic material, which can contribute to lower manufacturing costs and faster production times. Note however, that the interposer substrate 102 could also be formed from inorganic materials, such as silicon for example. Silicon can provide improved electrical properties for signal transfer and thermal properties for heat dissipation, such as if it was desired to provide improved heat dissipation from the die 106 through the interposer substrate 102 and through its insulating layers 142(1), 142(2) with its metal interconnects 138(1), 138(2) adjacent to the die 106 in the second, vertical direction (Z-axis direction). However, silicon may be a more expensive material than an organic material. Silicon may also require more sophisticated manufacturing processes to form and process its insulating layers and metal interconnects formed therein or thereon, which can be more complex leading to potentially increased fabrication costs and fabrication times.

Also note that the interposer substrate 102 could also be provided as other types of interposer substrates. As other examples, the interposer substrate 102 could also be provided as a modified semi-additive process (mSAP) interposer substrate, meaning that one or more of its metallization layers would include the metal interconnects that are formed adjacent to a respective insulating layer 142(1), 142(2). As another example, the interposer substrate 102 could be provided as a redistribution layer (RDL) substrate wherein one or more of its metallization layers would incorporate a RDL in which the metal interconnects could be formed and extend laterally in the first, horizontal direction(s) (X-axis and/or Y-axis directions) to redistribute electrical connections between the interposer substrate 102 and the package substrate 108. The RDLs can facilitate electrically connecting the package substrate 108 to the interposer substrate 102 in the event that their respective metal interconnects 114(1)-114(2), 138(1)-138(2) have different pitches.

In this example, as shown in FIG. 1B, the interposer substrate 102 also includes an outer layer 144 that is an outer, solder resist layer 144 in this example. An outer layer, including the outer layer 144, is a layer that forms an exterior side of the component device, which in this case is the interposer substrate 102. The outer, solder resist layer 144 is adjacent to the first metallization layer 136(1) of the interposer substrate 102 in the second, vertical direction (Z-axis direction). By the outer, solder resist layer 144 being adjacent to the first metallization layer 136(1), it is meant that the solder resist layer 144 is located beside or next to the first metallization layer 136(1) in the second, vertical direction (Z-axis direction). In this example, the solder resist layer 144 and first metallization layer 136(1) are directly adjacent to each other meaning each contacts the other. However, there could be intervening materials or coatings, for example, between the solder resist layer 144 and first metallization layer 136(1) such that the solder resist layer 144 and first metallization layer 136(1) are still adjacent to each other, but not directly adjacent to each other meaning directly contacting each other. The outer, solder resist layer 144 includes an outer insulating layer 146 with outer metal interconnects 148 in the form of metal posts 150 (as a form of metal interconnects (e.g., copper posts or pads)) exposed to allow the vertical interconnects 130 to be coupled to the metal posts 150 for signal routing between the interposer substrate 102 and the package substrate 108 of the die package 104. Note that although not shown, a second die and/or other electrical component can be coupled to the interposer substrate 102 for support and for signal routing through the interposer substrate 102 to the die package 104. In this instance, the IC package 100 can be thought of as a three-dimensional (3D) IC (3DIC) package.

With continuing reference to FIG. 1B, the metal posts 150 are formed on and coupled to the metal traces 140(1) in the first metallization layer 136(1) in this example, which can in turn be coupled to vias 152(1), which can be coupled to the metal traces 140(2) and vias 152(2) in the second metallization layer 136(2) to provide signal routing in the interposer substrate 102. In this example, the interposer substrate 102 also includes an outer solder resist layer 154 that includes its insulating layer 156 with metal interconnects 158 in the form of metal posts exposed to be electrically coupled to another electrical component coupled to the interposer substrate 102 for signal routing. The ETS interposer substrate 134 may be considered a three (3) layer (3L) substrate with its two (2) metallization layers 136(1), 136(2) and the solder resist layer 154. However, such is not limiting, and the interposer ETS package substrate 134 could have less than or more than three (3) layers (e.g., a two layer (2L) ETS interposer substrate or four layer (4L) ETS interposer substrate).

With continuing reference to FIG. 1B, as discussed in more detail below, the interposer substrate 102 includes a die cavity 162 that is integrated in the outer, solder resist layer 144 and a portion of the first metallization layer 136(1) of the interposer substrate 102. In this example, the die cavity 162 is formed by a void in the outer, solder resist layer 144 and a portion of the first metallization layer 136(1) adjacent to the outer, solder resist layer 144. For example, as discussed in more detail below, the die cavity 162 can be formed in the interposer substrate 102 by removing (e.g., etching) a portion of the insulating layer 146 of the outer, solder resist layer 144 and a portion of the insulating layer 142(1) of the first metallization layer 136(1) of the interposer substrate 102. The die cavity 162 allows an upper portion 164 of the first die 106 to extend into the area of the interposer substrate 102 in the second, vertical direction (Z-axis direction) where the solder resist layer 144 and a portion of the first metallization layer 136(1) would otherwise normally be present if the die cavity 162 were not provided. The die cavity 162 provides room for the first die 106 to at least partially extend into the die cavity 162 in the second, vertical direction (Z-axis direction) without necessarily having to increase the height of the mold layer 117 of the die package 104 in the second, vertical direction (Z-axis direction). For example, the first die 106 may have been increased in height to spread out the internal devices and internal interconnect layers to avoid or reduce hot spots of extreme temperatures inside the first die 106. In this example, the mold layer 117, by surrounding the first die 106, also in effect provides a second die cavity 166 for the first die 106, which is open to the die cavity 162 to provide a die cavity that can support the full height H₁ of the first die 106.

In this example, as shown in FIG. 1B, providing the die cavity 162 in the outer, solder resist layer 144 of the interposer substrate 102 allows an outer portion 168 of the outer, solder resist layer 144 that is outside of the die cavity 162 in the first, horizontal directions (X-axis and Y-axis directions) to extend further into the mold layer 117 of the die package 104 in the second, vertical direction (Z-axis direction) without interfering with the first die 106. This reduces the vertical distance D₁ between the interposer substrate 102 and the package substrate 108 in the second, vertical direction (Z-axis direction) where the vertical interconnects 130 are disposed to make vertical connections to facilitate the vertical interconnects 130 having a reduced aspect ratio with a reduced pitch P₁ to support dies with higher density input/output (I/O) connections. Thus, with the interposer substrate 102 provided in the IC package 100, vertical interconnections of reduced height and aspect ratio can be provided by a combination of first, reduced height metal posts 150 and vertical interconnects 130 in the outer, solder resist layer 144 coupled to second, reduced height vertical interconnects 130 in the mold layer 117 of the die package 104. This allows the vertical interconnections between the interposer substrate 102 and the package substrate 108 to be provided of a reduced pitch to support higher I/O density dies.

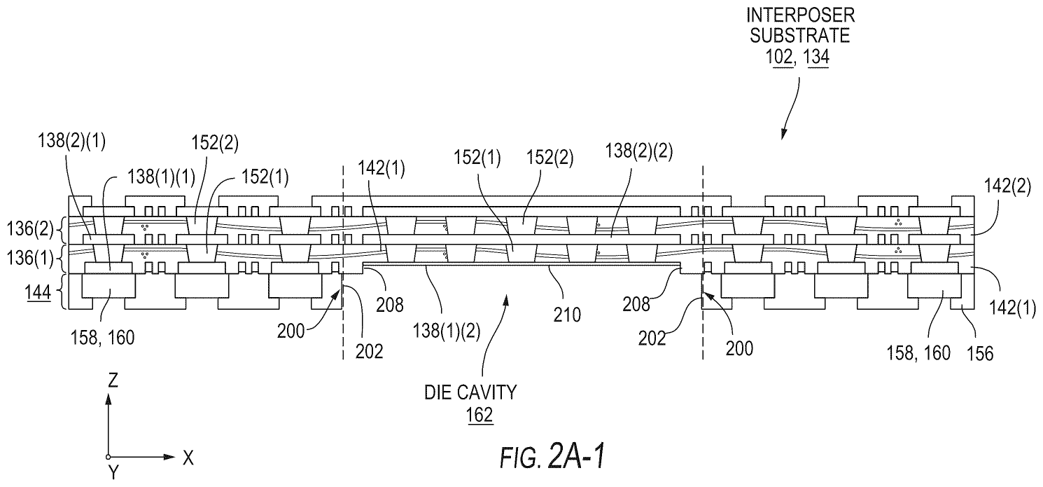

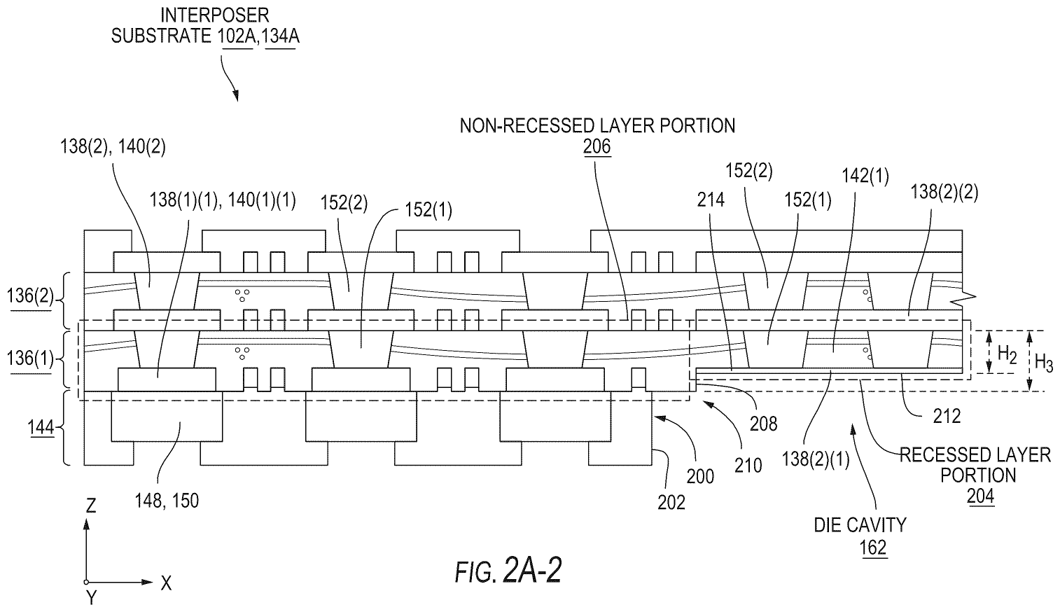

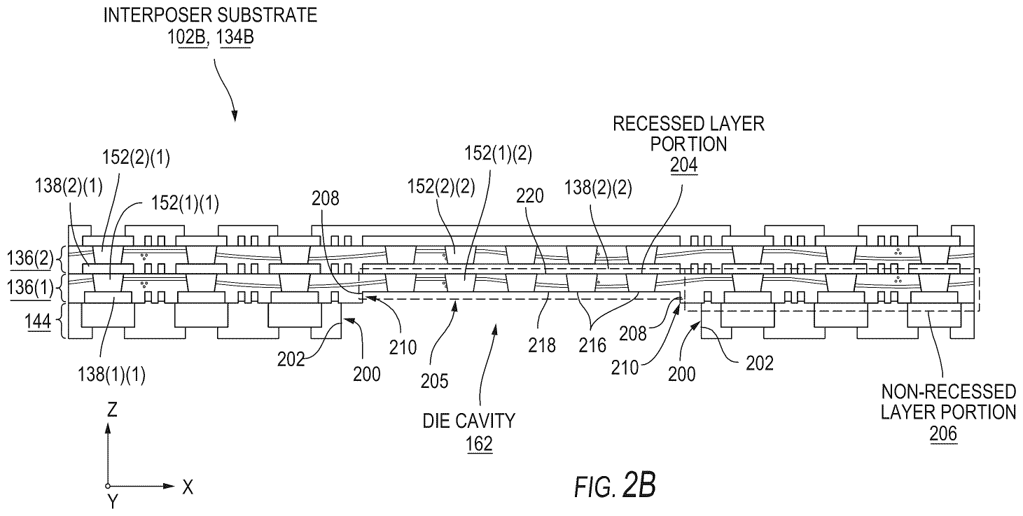

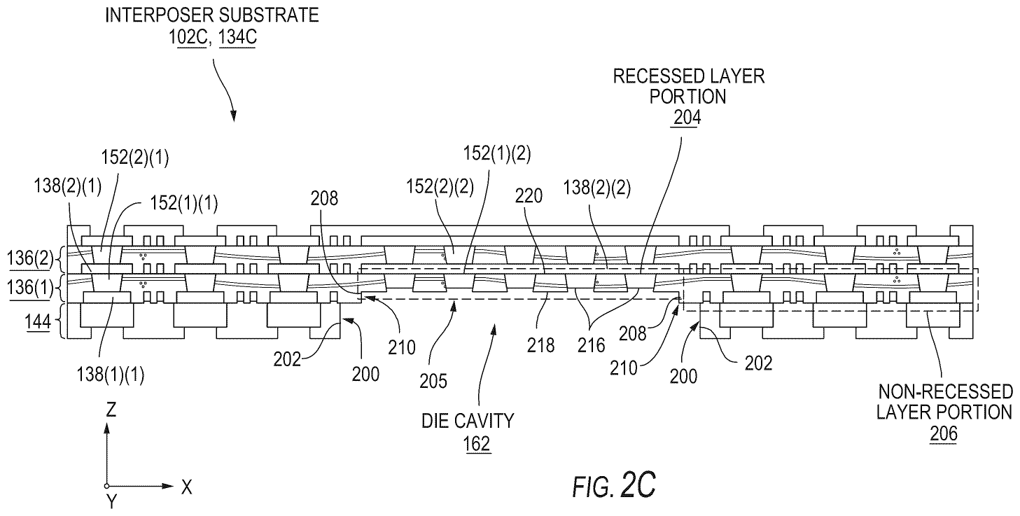

FIGS. 2A-1 and 2A-2 are a respective side view and close-up partial side view of an interposer substrate 102A in the form of an ETS interposer substrate 134A that can be provided as the interposer substrate 102 and ETS interposer substrate 134 in the IC package 100 in FIGS. 1A and 1B. Note that the interposer substrate 102A could be an organic interposer substrate or an inorganic interposer substrate, and could include one or more RDLs as discussed above for the interposer substrate 102. Common elements between the interposer substrate 102A, 134A in FIGS. 2A-1 and 2A-2 and the interposer substrate 102, 134 in FIGS. 1A and 1B are shown with common element numbers.

As shown in FIGS. 2A-1 and 2A-2, a first step structure 200 is formed where the portion of the solder resist layer 144 is removed to form a side wall 202 to form the die cavity 162 as a step die cavity 162 integrated in the solder resist layer 144. The die cavity 162 in this example is also formed by a void or removal of material from the outer, solder resist layer 144 and also a portion of the first metallization layer 136(1). As shown in FIG. 2A-2, removal or void of material in the first metallization layer 136(1) creates a recessed layer portion 204 of the first metallization layer 136(1) of height H₂ intersecting the die cavity 162 in the first, horizontal direction (X-axis and/or Y-axis directions), and a non-recessed layer portion 206 of the first metallization layer 136(1) of height H₃ outside the die cavity 162, not intersecting the die cavity 162 in the first, horizontal direction (X-axis and/or Y-axis directions). The recessed layer portion 204 forms a recessed region 205 in the first metallization layer 136(1), wherein the recessed region 205 forms part of the die cavity 162. Also, as shown in FIG. 2A-2, in this example, because a side wall 208 of the first metallization layer 136(1) formed from the portion of the first metallization layer 136(1) removed to form the die cavity 162 is not co-planar with the side wall 202 of the solder resist layer 144 in the second, vertical direction (Z-axis direction), a second step structure 210 is formed by the removed portion of the first metallization layer 136(1) adjacent to the die cavity 162. The second step structure 210 is formed from the interface of the non-recessed layer portion 206 to the recessed layer portion 204 of the first metallization layer 136(1). However, because the second step structure 210 is formed as a result of removal of a portion of the first metallization layer 136(1), which may be a more rigid material, such as a pre-impregnated glass (PPG) material, the presence of the recessed layer portion 204 of the first metallization layer 136(1) will still be rigid enough to not make the interposer substrate 102A susceptible to warpage and risk delamination in the first metallization layer 136(1).

With continuing reference to FIGS. 2A-1 and 2A-2, some first metal interconnects 138(1)(1), 138(2)(1) are outside of the die cavity 162 in the first horizontal direction(s) (X-axis and/or Y-axis directions), meaning the first metal interconnects 138(1)(1), 138(2)(1) do not intersect the die cavity 162 in the first horizontal direction(s) (X-axis and/or Y-axis directions). The metal posts 150 of the solder resist layer 144 are also outside of the die cavity 162 in the first horizontal direction(s) (X-axis and/or Y-axis directions), meaning the metal posts 150 do not intersect the die cavity 162 in the first horizontal direction(s) (X-axis and/or Y-axis directions). However, other first metal interconnects 138(1)(2), 138(2)(2) are inside the die cavity 162 in the first horizontal direction(s) (X-axis and/or Y-axis directions), meaning these other first metal interconnects 138(1)(2), 138(2)(2) do intersect and are adjacent to the die cavity 162 in the first horizontal direction(s) (X-axis and/or Y-axis directions). Note that the metal interconnects 138(1)(2), 138(2)(2) could be fully or only partially inside the die cavity 162 in the first horizontal direction(s) (X-axis and/or Y-axis directions). In this example, since a portion of the first metallization layer 136(1) has been removed to a lower surface 212 of the first metal interconnect 138(1)(2) adjacent to the die cavity 162 as shown in FIG. 2A-2, this means that the first metal interconnect 138(1)(2) is located closer to the die cavity 162, wherein its thermal coupling to the die cavity 162 can provide increased thermal coupling and heat dissipation for a die extended into the die cavity 162. In this manner, the lower surface 212 of the first metal interconnect 138(1)(2) is directly adjacent to the die cavity 162 meaning the first metal interconnect 138(1)(2) is directly accessible through the die cavity 162. However, the lower surface 212 of the first metal interconnect 138(1)(2) could also be indirectly adjacent to the die cavity 216 meaning there may be an intervening component or material between the lower surface 212 of the first metal interconnect 138(1)(2) and the die cavity 162.

Also, in this example, as shown in FIG. 2A-2, the lower surface 212 of the first metal interconnect 138(1)(2) is exposed to the die cavity 162 in this example to enhance thermal coupling so that material of the insulating layer 142(1) is not disposed between the lower surface 212 of the first metal interconnect 138(2)(1) and the die cavity 162, but such is not required. In this example, as shown in FIGS. 2A-1 and 2A-2, the first metal interconnect 138(1)(2) is in the form of a metal plate 214 to provide a larger area of metal material to provide increased thermal coupling to the die cavity 162 for heat dissipation. In this example, the first metallization layer 136(1) also includes its vias 152(1) coupled to the metal plate 214 and to the other metal interconnects 138(2)(2) and vias 152(2) to provide a thermal conducting path through the interposer substrate 102A for improved heat dissipation.

FIG. 2B is a side view of another exemplary interposer substrate 102B in the form of an ETS interposer substrate 134B that can be provided as the interposer substrate 102 and ETS interposer substrate 134 in the IC package 100 in FIGS. 1A and 1B. Note that the interposer substrate 102B could be an organic interposer substrate or an inorganic interposer substrate, and could include one or more RDLs as discussed above for the interposer substrate 102. Common elements between the interposer substrate 102B, 134B in FIG. 2B and the interposer substrates 102, 102A, 134, 134A in FIGS. 1A-1B, 2A-1, and 2A-2 are shown with common element numbers.

With reference to FIG. 2B, some vias 152(1)(1), 152(2)(1) as a form of metal interconnects are outside of the die cavity 162 in the first horizontal direction(s) (X-axis and/or Y-axis directions), meaning the vias 152(1)(1), 152(2)(1) do not intersect the die cavity 162 in the first horizontal direction(s) (X-axis and/or Y-axis directions). However, other vias 152(1)(2), 152(2)(2) as a form of metal interconnects are inside the die cavity 162 in the first horizontal direction(s) (X-axis and/or Y-axis directions), meaning these other vias 152(1)(2), 152(2)(2) do intersect and are adjacent to the die cavity 162 in the first horizontal direction(s) (X-axis and/or Y-axis directions). In this example, since a portion of the first metallization layer 136(1) has been removed to a bottom surface 216 of the vias 152(1)(2) adjacent to the die cavity 162, this means that the vias 152(1)(2) are located close to the die cavity 162, wherein its thermal coupling to the die cavity 162 can provide increased thermal coupling and heat dissipation for a die extended into the die cavity 162.

Also, in this example, as shown in FIG. 2B, the bottom surfaces 216 of the vias 152(1)(2) are exposed to the die cavity 162 in this example to enhance thermal coupling so that material of the insulating layer 142(1) is not disposed between the bottom surface 216 of the vias 152(1)(2) and the die cavity 162, but such is not required. In this manner, the bottom surfaces 216 of the vias 152(1)(2) are directly adjacent to the die cavity 162 meaning the vias 152(1)(2) are directly accessible through the die cavity 162. However, the bottom surfaces 216 of the vias 152(1)(2) could also be indirectly adjacent to the die cavity 216 meaning there may be an intervening component or material between the bottom surfaces 216 of the vias 152(1)(2) and the die cavity 162. In this example, the bottom surfaces 216 of the vias 152(1)(2) are co-planar with a first, bottom surface 218 of the recessed layer portion 204 of the first metallization layer 136(1). The first, bottom surface 218 is opposite to a second, top surface 220 of the first metallization layer 136(1) in the second, vertical direction (Z-axis direction). In this example, the first metallization layer 136(1) also includes its vias 152(1)(2) coupled to the metal interconnects 138(2)(2) and vias 152(2)(2) to provide a thermal conducting path through the interposer substrate 102B for improved heat dissipation.

FIG. 2C is a side view of another exemplary interposer substrate 102C in the form of an ETS interposer substrate 134C that can be provided as the interposer substrate 102 and ETS interposer substrate 134 in the IC package 100 in FIGS. 1A and 1B. Note that the interposer substrate 102C could be an organic interposer substrate or an inorganic interposer substrate, and could include one or more RDLs as discussed above for the interposer substrate 102. Common elements between the interposer substrate 102C, 134C in FIG. 2C and the interposer substrates 102, 102A, 102B, 134, 134A, 134B in FIGS. 1A-2B are shown with common element numbers.

With reference to FIG. 2C, the vias 152(1)(2), 152(2)(2) as a form of metal interconnects are inside the die cavity 162 in the first horizontal direction(s) (X-axis and/or Y-axis directions) like in the interposer substrate 102B in FIG. 2B. However, in this example, the bottom surfaces 216 of the vias 152(2)(1) are recessed from the bottom surface 218 of the recessed layer portion 204 of the first metallization layer 136(1). This may be as a result of the etching or removal process to remove a metal portion of the vias 152(1)(2) in the first metallization layer 136(1). In this example, the bottom surfaces 216 of the vias 152(1)(2) are still exposed to the die cavity 162 for improved thermal coupling. In this example, the bottom surfaces 216 of the vias 152(1)(2) are directly adjacent to the die cavity 162 meaning the vias 152(1)(2) are directly accessible through the die cavity 162. However, the bottom surfaces 216 of the vias 152(1)(2) could also be indirectly adjacent to the die cavity 216 meaning there may be an intervening component or material between the bottom surfaces 216 of the vias 152(1)(2) and the die cavity 162.

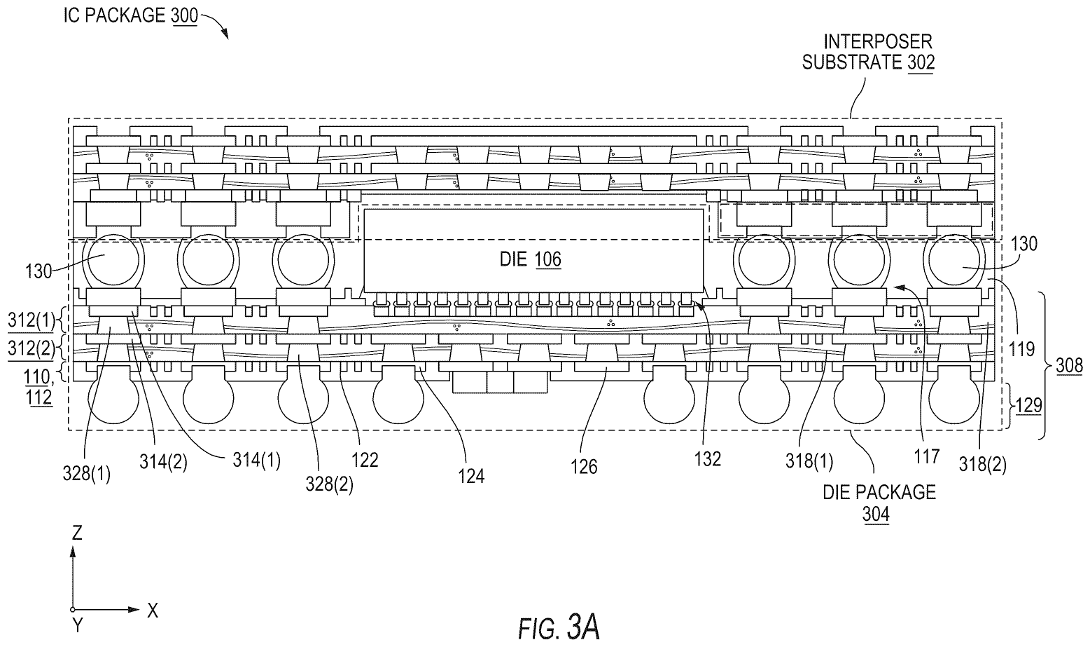

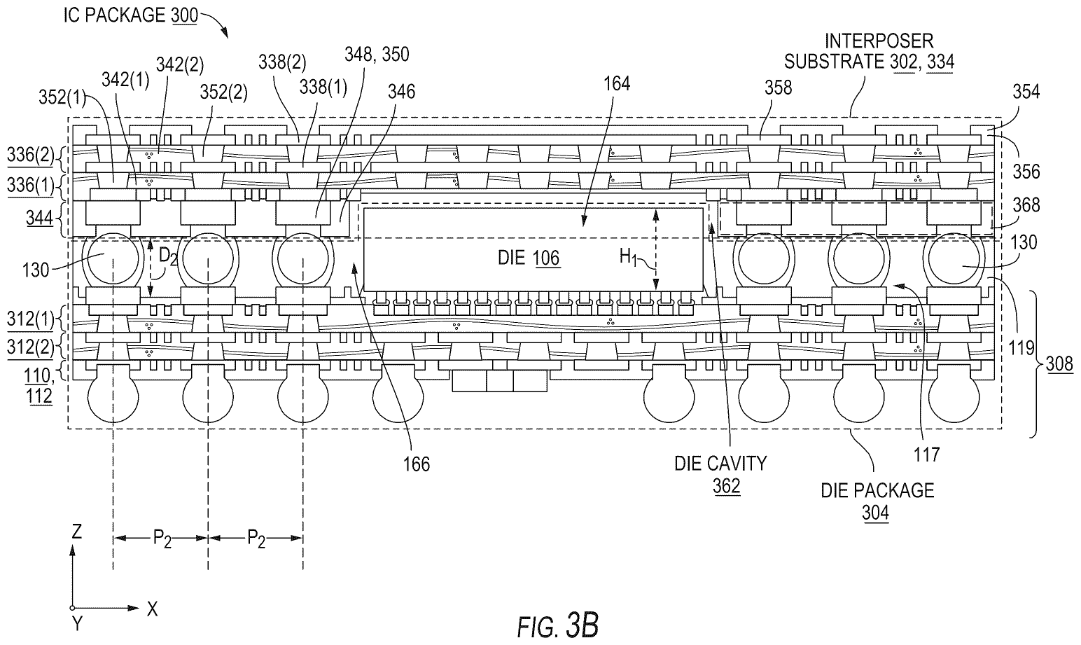

FIGS. 3A and 3B are side views of another exemplary IC package 300 that also includes a coreless interposer substrate 302 coupled to a die package 304. As shown in FIG. 3A, the interposer substrate 302 is a coreless interposer substrate 302 in that it does not include a core layer provided to reinforce the rigidity of the interposer substrate 302. Note that the interposer substrate 302 could be an organic interposer substrate or an inorganic interposer substrate, and could include one or more RDLs as discussed above for the interposer substrate 102. Common elements between the IC package 300 in FIGS. 3A and 3B and the IC package 100 in FIGS. 1A and 1B are shown with common element numbers.

However, in the IC package 300 as shown in FIG. 3A, a package substrate 308 of the die package 304 is a modified semi-additive process (mSAP) package substrate 308, meaning that one or more of its metallization layers 312(1), 312(2) (also referred to as mSAP metallization layers 312(1), 312(2)) include respective metal interconnects 314(1), 314(2) that are formed adjacent to a respective insulating layer 318(1), 318(2). The metallization layers 312(1), 312(2) extend in a first, horizontal direction (X-axis and Y-axis directions). The metal interconnects 314(1), 314(2) can be formed to facilitate both horizontal routing in the first, horizontal direction (X-axis and/or Y-axis directions) and vertical routing in the second, vertical direction (Z-axis direction). The die package 304 includes the mold layer 117 of the mold material 119 that is disposed on the package substrate 308 and around and adjacent to the first die 106 to insulate the vertical interconnects 130 and the die interconnects 132 of the first die 106 as well as provide stability to the first die 106.

In this example, the package substrate 308 of the die package 304 also includes the outer layer 110 that is the outer, solder resist layer 120 in this example. The outer, solder resist layer 120 is adjacent to the second metallization layer 312(2) in the second, vertical direction (Z-axis direction). The outer, solder resist layer 120 includes the outer insulating layer 122 with metal interconnects 124 in the form of metal posts 126 exposed to allow external metal interconnects 129 (e.g., solder balls) to be coupled to the metal posts 126 for external signal routing. The mSAP package substrate 308 may be considered a three (3) layer (3L) substrate with its two (2) metallization layers 312(1), 312(2) and the solder resist layer 120. However, such is not limiting, and mSAP package substrate 308 could have less than or more than three (3) layers (e.g., a two layer (2L) package substrate or four layer (4L) package substrate). The metal posts 126 are formed on and coupled to vias 328(2) in the second metallization layer 312(2) in this example, which can in turn be coupled to the metal interconnects 314(2), which can be coupled to vias 328(1) and the metal interconnects 314(1) in the first metallization layer 312(1) to provide signal routing in the package substrate 308. In this example, signal routing is provided from the external metal interconnects 129 through the package substrate 308 and to the vertical interconnects 130 (e.g., solder balls, ball grid array (BGA) interconnects) that are coupled to the interposer substrate 302. The die interconnects 132 of the first die 106 are also coupled to the first metallization layer 312(1) of the package substrate 308 to provide signal routing to the first die 106, which can be from the external metal interconnects 129 or the interposer substrate 302 through the vertical interconnects 130.

As shown in FIG. 3B, the coreless interposer substrate 302 of the IC package 300 in this example is also a coreless mSAP interposer substrate 334 meaning that one or more of its metallization layers 336(1), 336(2) (also referred to as mSAP metallization layers 336(1) 336(2)) include respective metal interconnects 338(1), 338(2) formed adjacent to a respective insulating layer 342(1), 342(2). Note that the first metallization layer 336(1) is an outer layer/outer metallization layer with respect to the metallization layers 336(1), 336(2) in that the first metallization layer 336(1) forms an exterior side of the metallization layers 336(1), 336(2). The metallization layers 336(1), 336(2) extend in the first, horizontal direction (X-axis and Y-axis directions). The metal interconnects 338(1), 338(2) can be formed to facilitate both horizontal routing in the first, horizontal direction (X-axis and/or Y-axis directions) and vertical routing in the second, vertical direction (Z-axis direction).

In this example, the interposer substrate 302 also includes an outer layer 344 that is an outer, solder resist layer 344 in this example. An outer layer, including the outer layer 344, is a layer that forms an exterior side of the component device, which in this case is the interposer substrate 302. The outer, solder resist layer 344 is adjacent to the first metallization layer 336(1) of the interposer substrate 302 in the second, vertical direction (Z-axis direction). By the outer, solder resist layer 344 being adjacent to the first metallization layer 336(1), it is meant that the solder resist layer 344 is located beside or next to the first metallization layer 336(1) in the second, vertical direction (Z-axis direction). In this example, the solder resist layer 344 and first metallization layer 336(1) are directly adjacent to each other meaning each contacts the other. However, there could be intervening materials or coatings, for example, between the solder resist layer 344 and first metallization layer 336(1) such that the solder resist layer 344 and first metallization layer 336(1) are still adjacent to each other, but not directly adjacent to each other meaning directly contacting each other.

The outer, solder resist layer 344 includes an outer insulating layer 346 with outer metal interconnects 348 in the form of metal posts 350 (as a form of metal interconnects (e.g., copper posts)) exposed to allow the vertical interconnects 130 to be coupled to the metal posts 350 for signal routing between the interposer substrate 302 and the package substrate 308 of the die package 304. Note that although not shown, a second die and/or other electrical component can be coupled to the interposer substrate 302 for support and for signal routing through the interposer substrate 302 to the die package 304. In this instance, the IC package 300 can be thought of as a 3DIC package. The metal posts 350 are formed on and coupled to the metal interconnects 338(1) in the first metallization layer 336(1) in this example, which can in turn be coupled to vias 352(1), which can be coupled to the metal interconnects 338(2) and vias 352(2) in the second metallization layer 336(2) to provide signal routing in the interposer substrate 302. In this example, the interposer substrate 302 also includes the outer solder resist layer 354 that includes its insulating layer 356 with openings 358 to expose the second metal interconnects 338(2) in the second metallization layer 336(2). The mSAP interposer substrate 334 may be considered a three (3) layer (3L) substrate with its two (2) metallization layers 336(1), 336(2) and the solder resist layer 354. However, such is not limiting, and the mSAP interposer substrate 334 could have less than or more than three (3) layers (e.g., a two layer (2L) interposer substrate or four layer (4L) interposer substrate).

With continuing reference to FIG. 3B, the interposer substrate 302 includes a die cavity 362 that is integrated in the outer, solder resist layer 344. In this example, the die cavity 362 is formed by a void in the outer, solder resist layer 344. For example, as discussed in more detail below, the die cavity 362 is formed in this example in the interposer substrate 302 by removing (e.g., etching) a portion of the insulating layer 346 of the outer, solder resist layer 344, but not from a removed portion of the first metallization layer 336(1) like provided in the IC package 100 in FIGS. 1A and 1B. The die cavity 362 allows the upper portion 164 of the first die 106 to extend into the area of the interposer substrate 302 in the second, vertical direction (Z-axis direction) where the solder resist layer 344 would otherwise normally be present if the die cavity 362 were not provided. The die cavity 362 provides room for the first die 306 to at least partially extend into the die cavity 362 in the second, vertical direction (Z-axis direction) without necessarily having to increase the height of the mold layer 117 of the die package 304 in the second, vertical direction (Z-axis direction). The mold layer 117, by surrounding the first die 106, also in effect provides the second die cavity 166 for the first die 106, which is open to the die cavity 362 to provide a die cavity that can support the full height H₁ of the first die 106.

In this example, providing the die cavity 362 in the outer, solder resist layer 344 of the interposer substrate 302 allows an outer portion 368 of the outer, solder resist layer 344 that is outside of the die cavity 362 in the first, horizontal direction (X-axis and Y-axis directions) to extend further into the mold layer 117 of the die package 304 in the second, vertical direction (Z-axis direction) without interfering with the first die 106. This reduces the vertical distance D2 between the interposer substrate 302 and the package substrate 308 in the second, vertical direction (Z-axis direction) where the vertical interconnects 130 are disposed to make vertical connections to facilitate the vertical interconnects 130 having a reduced aspect ratio with a reduced pitch P₂ to support dies with higher density I/O connections. Thus, with the interposer substrate 302 provided in the IC package 300, vertical interconnections of reduced height and aspect ratio can be provided by a combination of first, reduced height metal posts 350 and vertical interconnects 130 in the outer, solder resist layer 344 coupled to second, reduced height vertical interconnects 130 in the mold layer 117 of the die package 304. This allows the vertical interconnections between the interposer substrate 302 and the package substrate 308 to be provided of a reduced pitch to support higher I/O density dies.

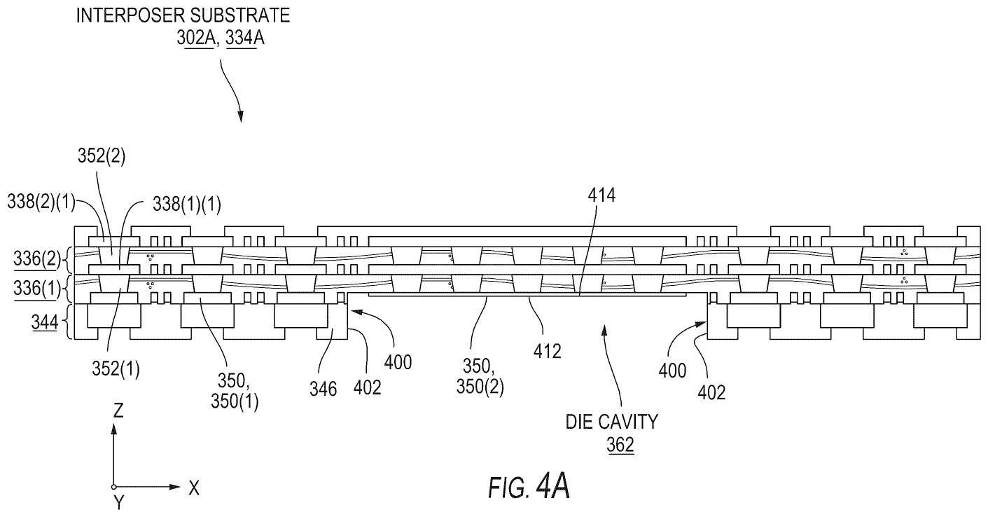

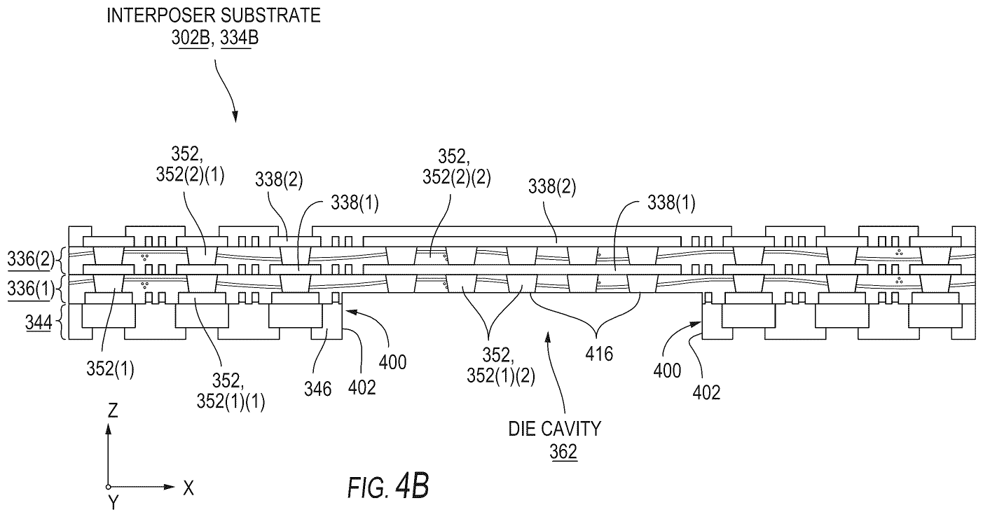

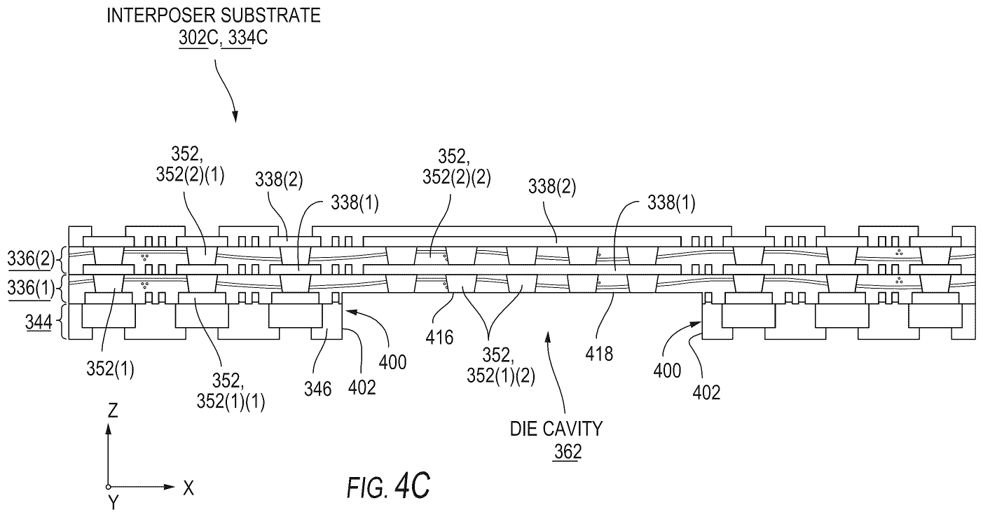

FIG. 4A is a respective side view of another interposer substrate 302A in the form of a cored mSAP interposer substrate 334A that can be provided as the interposer substrate 302 in the IC package 300 in FIGS. 3A and 3B. Note that the interposer substrate 302A could be an organic interposer substrate or an inorganic interposer substrate, and could include one or more RDLs as discussed above for the interposer substrate 102. Common elements between the interposer substrate 302A, 334A in FIG. 4A and the interposer substrate 302, 334 in FIGS. 3A and 3B are shown with common element numbers.

As shown in FIG. 4A, a first step structure 400 is formed where the portion of the solder resist layer 344 is removed to form a side wall 402 to form the die cavity 362 as a step die cavity 362 integrated in the solder resist layer 344. Some first metal interconnects 338(1)(1), 338(2)(1) are outside of die cavity 362 in the first horizontal direction(s) (X-axis and/or Y-axis directions), meaning the first metal interconnects 338(1)(1), 338(2)(1) do not intersect the die cavity 362 in the first horizontal direction(s) (X-axis and/or Y-axis directions). Some metal posts 350(1) of the solder resist layer 344 are also outside of the die cavity 362 in the first horizontal direction(s) (X-axis and/or Y-axis directions), meaning the metal posts 350(1) do not intersect the die cavity 362 in the first horizontal direction(s) (X-axis and/or Y-axis directions). However, another metal post 350(2) of the solder resist layer 344 is inside the die cavity 362 in the first horizontal direction(s) (X-axis and/or Y-axis directions), meaning this other metal post 350(2) does intersect and is adjacent to the die cavity 362 in the first horizontal direction(s) (X-axis and/or Y-axis directions). In this example, since a portion of the solder resist layer 344 has been removed to a bottom surface 412 of the metal post 350(2) adjacent to the die cavity 362, this means that the metal post 350(2) is located closer to the die cavity 362, wherein its thermal coupling to the die cavity 362 can provide increased thermal coupling and heat dissipation for a die extended into the die cavity 362. In this example, the bottom surface 412 of the metal post 350(2) is directly adjacent to the die cavity 362 meaning the bottom surface 412 of the metal post 350(2) is directly accessible through the die cavity 362. However, the bottom surface 412 of the metal post 350(2) could also be indirectly adjacent to the die cavity 362 meaning there may be an intervening component or material between the bottom surface 412 of the metal post 350(2) and the die cavity 362.

Also, in this example, the bottom surface 412 of the metal post 350(2) is exposed to the die cavity 362 in this example to enhance thermal coupling so that material of the insulating layer 346 is not disposed between the bottom surface 412 of the metal post 350(2) and the die cavity 362, but such is not required. In this example, the metal post 350(2) is in the form of a metal plate 414 to provide a larger area of metal material to provide increased thermal coupling to the die cavity 362 for heat dissipation. In this example, the first metallization layer 336(1) also includes its vias 352(1) coupled to the metal plate 414 and to the other metal interconnects 338(1)(1), 338(2)(1) and vias 352(2) to provide a thermal conducting path through the interposer substrate 302A for improved heat dissipation.

FIG. 4B is a side view of another exemplary interposer substrate 302B in the form of a coreless mSAP interposer substrate 334B that can be provided as the interposer substrate 302 in the IC package 300 in FIGS. 3A and 3B. Note that the interposer substrate 302B could be an organic interposer substrate or an inorganic interposer substrate, and could include one or more RDLs as discussed above for the interposer substrate 102. Common elements between the interposer substrate 302B, 334B in FIG. 4B and the interposer substrates 302, 302A, 334, 334A in FIGS. 3A-3B and 4A are shown with common element numbers.

With reference to FIG. 4B, some vias 352(1)(1), 352(2)(1) of the first metallization layer 336(1) as a form of metal interconnects are outside of die cavity 362 in the first horizontal direction(s) (X-axis and/or Y-axis directions), meaning the vias 352(1)(1), 352(1)(2) do not intersect the die cavity 362 in the first horizontal direction(s) (X-axis and/or Y-axis directions). However, other vias 352(1)(2), 352(2)(2) of the first metallization layer 336(1) as a form of metal interconnects are inside the die cavity 362 in the first horizontal direction(s) (X-axis and/or Y-axis directions), meaning these other vias 352(1)(2), 352(2)(2) do intersect and are adjacent to the die cavity 362 in the first horizontal direction(s) (X-axis and/or Y-axis directions). In this example, the first metallization layer 336(1) is an mSAP metallization layer, meaning that the vias 352(1)(2) are located close to the die cavity 362, wherein its thermal coupling to the die cavity 362 can provide increased thermal coupling and heat dissipation for a die extended into the die cavity 362.

Also, in this example, as shown in FIG. 4B, lower surfaces 416 of the vias 352(1)(2) are exposed to the die cavity 362 in this example to enhance thermal coupling so that the material of the insulating layer 346 is not disposed between the lower surfaces 416 of the vias 352(1)(2) and the die cavity 362, but such is not required. In this example, the first metal interconnect layer 336(1) also includes its metal interconnects 338(1) coupled to the metal interconnects 338(2) and vias 352(2)(2) to provide a thermal conducting path through the interposer substrate 302B for improved heat dissipation. In this example, the lower surfaces 416 of the vias 352(1)(2) are directly adjacent to the die cavity 362 meaning the lower surfaces 416 of the vias 352(1)(2) are directly accessible through the die cavity 362. However, the lower surfaces 416 of the vias 352(1)(2) could also be indirectly adjacent to the die cavity 362 meaning there may be an intervening component or material between the lower surfaces 416 of the vias 352(1)(2) and the die cavity 362.

FIG. 4C is a side view of another exemplary interposer substrate 302C in the form of a coreless mSAP interposer substrate 334C that can be provided as the interposer substrate 302 in the IC package 300 in FIGS. 3A and 3B. Note that the interposer substrate 302C could be an organic interposer substrate or an inorganic interposer substrate, and could include one or more RDLs as discussed above for the interposer substrate 102. Common elements between the interposer substrate 302C, 334C in FIG. 4C and the interposer substrates 302, 302A, 302B, 334, 334A, 334B in FIGS. 3A-3B and 4B are shown with common element numbers.

With reference to FIG. 4C, the vias 352(1)(2), 352(2)(2) as a form of metal interconnects are inside the die cavity 362 in the first horizontal direction(s) (X-axis and/or Y-axis directions) like in the interposer substrate 302B in FIG. 4B. However, in this example, the lower surfaces 416 of the vias 352(1)(2) are recessed from a bottom surface 418 of the first metallization layer 336(1). This may be as a result of the etching or removal process to remove a metal portion of the vias 352(1)(2) in the first metallization layer 336(1). In this example, the lower surfaces 416 of the vias 352(1)(2) are still exposed to the die cavity 362 for improved thermal coupling. In this example, the lower surfaces 416 of the vias 352(1)(2) are directly adjacent to the die cavity 362 meaning the lower surfaces 416 of the vias 352(1)(2) are directly accessible through the die cavity 362. However, the lower surfaces 416 of the vias 352(1)(2) could also be indirectly adjacent to the die cavity 362 meaning there may be an intervening component or material between the lower surfaces 416 of the vias 352(1)(2) and the die cavity 362.

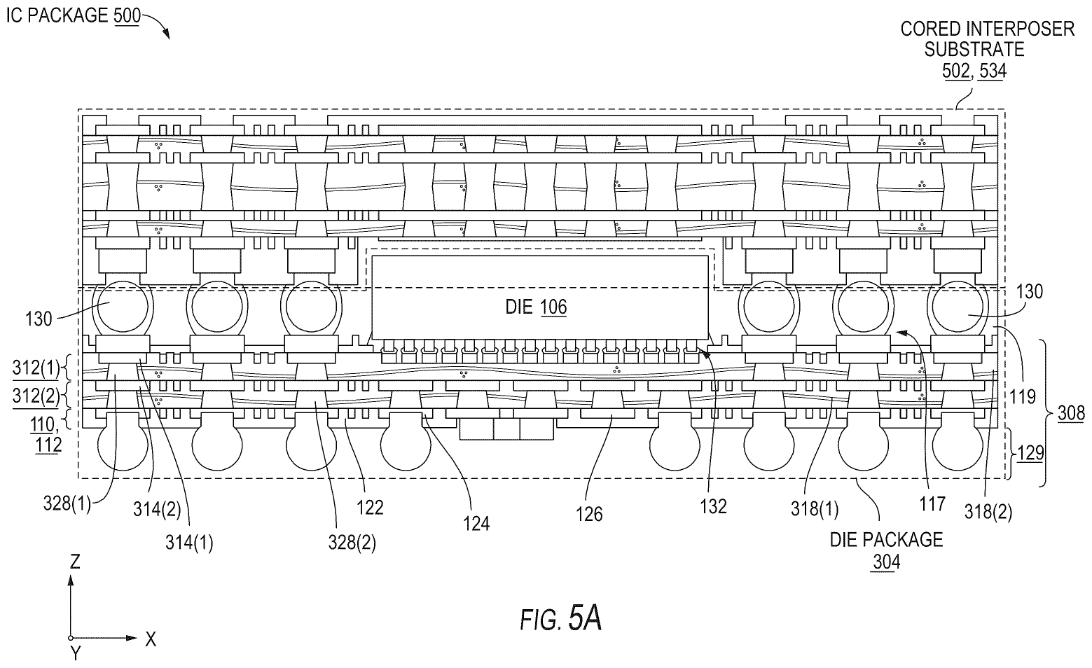

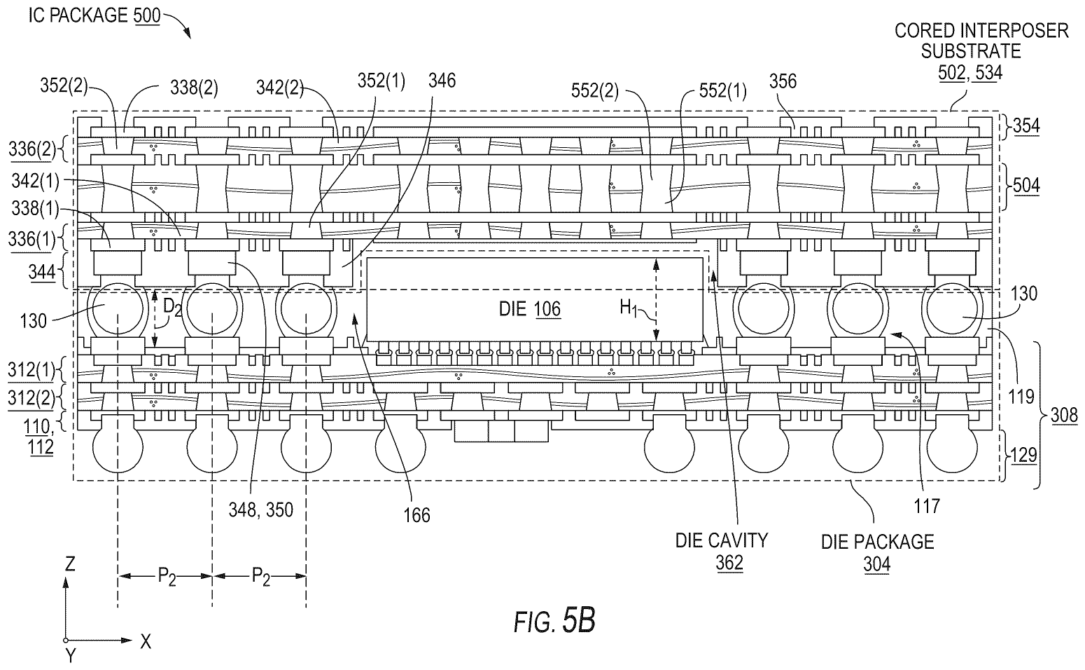

FIGS. 5A and 5B are side views of another exemplary IC package 500 that also includes a cored interposer substrate 502 coupled to the die package 304 like in the IC package 300 in FIGS. 3A and 3B. As shown in FIG. 5A, the interposer substrate 502 is a cored interposer substrate 502 in that it includes a core layer 504 provided to reinforce the rigidity of the interposer substrate 502. Note that the interposer substrate 502 could be an organic interposer substrate or an inorganic interposer substrate, and could include one or more RDLs as discussed above for the interposer substrate 102. Common elements between the IC package 500 in FIGS. 5A and 5B and the IC package 300 in FIGS. 3A and 3B are shown with common element numbers.

As shown in FIG. 5A, the IC package 500 includes a cored interposer substrate 502 as a cored mSAP interposer substrate 534. As shown in FIG. 5B, the interposer substrate 502 being a cored mSAP interposer substrate 534 means that one or more of its metallization layers 336(1), 336(2) (also referred to as mSAP metallization layers 336(1) 336(2)) include respective metal interconnects 338(1), 338(2) formed adjacent to a respective insulating layer 342(1), 342(2). The metallization layers 336(1), 336(2) extend in a first, horizontal direction (X-axis and Y-axis directions). The metal interconnects 338(1), 338(2) can be formed to facilitate both horizontal routing in the first, horizontal direction (X-axis and/or Y-axis directions) and vertical routing in the second, vertical direction (Z-axis direction). The core layer 504 is disposed between and coupled to the metallization layers 336(1), 336(2) in the second, vertical direction (Z-axis direction). In this example, the core layer 504 includes vias 552(1), 552(2) that couple the first metal interconnects 338(1) to the second metal interconnects 338(2) to provide signal routing through the core layer 504.

With continuing reference to FIG. 5B, the interposer substrate 502 includes the die cavity 362 that is integrated in the outer, solder resist layer 344 like in the interposer substrate 302 in FIGS. 3A and 3B. The details of the die cavity 362 are described above with regard to the IC package 300 in FIGS. 3A and 3B.

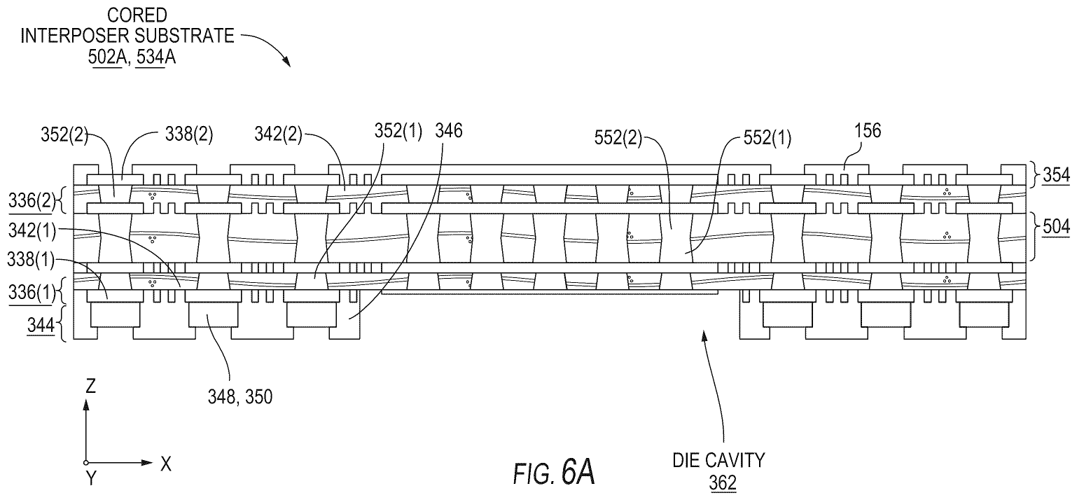

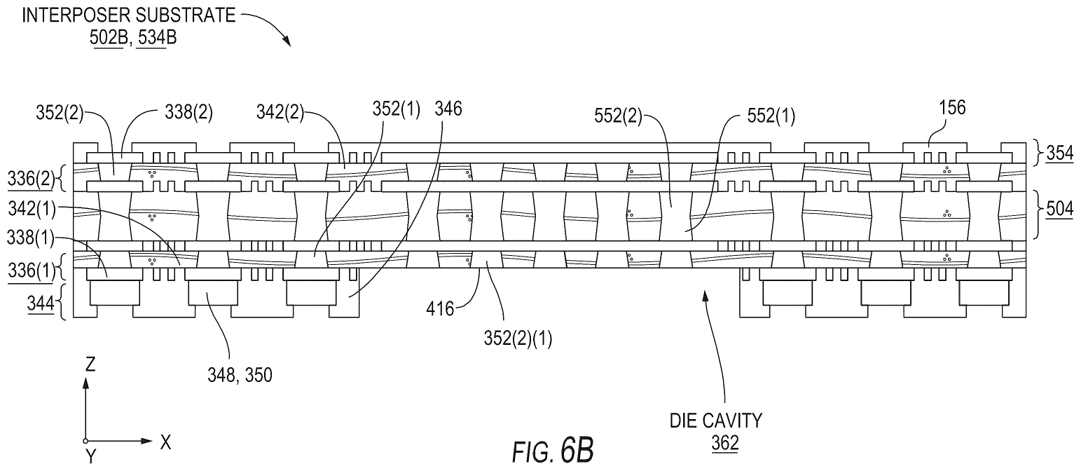

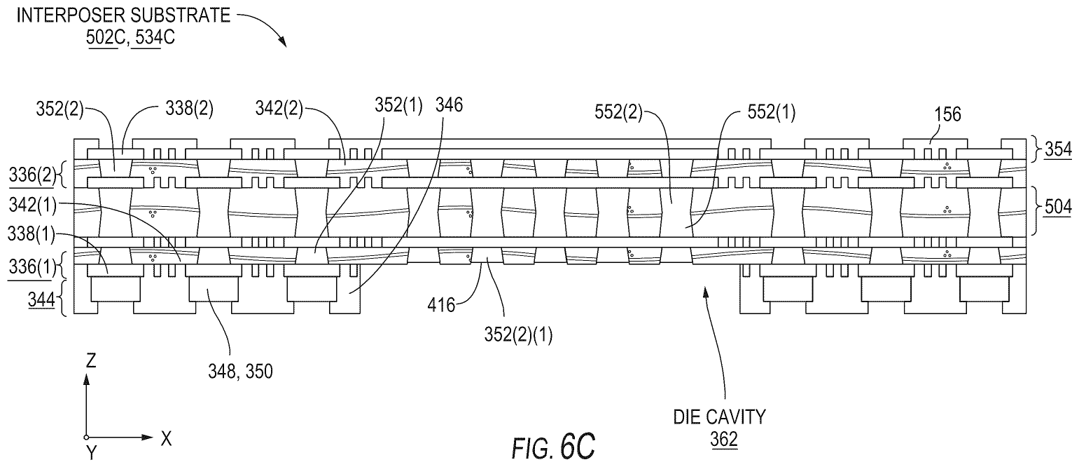

FIG. 6A is a respective side view of another exemplary interposer substrate 502A in the form of a cored mSAP interposer substrate 534A that can be provided as the interposer substrate 502 in the IC package 500 in FIGS. 5A and 5B. Common elements between the interposer substrate 502A, 534A in FIG. 6A and the interposer substrate 502, 534 in FIGS. 5A and 5B are shown with common element numbers. Note that the interposer substrate 502A could be an organic interposer substrate or an inorganic interposer substrate, and could include one or more RDLs as discussed above for the interposer substrate 102. In this example, like the interposer substrate 302A in FIG. 4A, the metal post 350(2) is in the form of the metal plate 414 to provide a larger area of metal material to provide increased thermal coupling to the die cavity 362 for heat dissipation. Other details for common elements between the interposer substrate 502A, 534A in FIG. 6A and the interposer substrate 502, 534 in FIGS. 5A and 5B are as described previously.

FIG. 6B is a side view of another exemplary interposer substrate 502B in the form of a cored mSAP interposer substrate 534B that can be provided as the interposer substrate 502 in the IC package 500 in FIGS. 5A and 5B. Common elements between the interposer substrate 502B, 534B in FIG. 6B and the interposer substrates 502, 502A, 534, 534A in FIGS. 5A-5B and 6A are shown with common element numbers. Note that the interposer substrate 502B could be an organic interposer substrate or an inorganic interposer substrate, and could include one or more RDLs as discussed above for the interposer substrate 102. Like discussed in the example interposer substrate 302B, 334B in FIG. 4B, the lower surfaces 416 of the vias 352(1)(2) in the first metallization layer 336(1) in the interposer substrate 502B in FIG. 6B are exposed to the die cavity 362 in this example to enhance thermal coupling so that material of the insulating layer 346 is not disposed between the lower surfaces 416 of the vias 352(1)(2) and the die cavity 362, but such is not required. Other details for common elements between the interposer substrate 502B, 534B in FIG. 6B and the interposer substrate 502, 534 in FIGS. 5A and 5B are as described previously.

FIG. 6C is a side view of another exemplary interposer substrate 502C in the form of a cored mSAP interposer substrate 534C that can be provided as the interposer substrate 502 in the IC package 500 in FIGS. 5A and 5B. Common elements between the interposer substrate 502C, 534C in FIG. 6C and the interposer substrates 502, 502A, 502B, 534, 534A, 534B in FIGS. 5A-6B are shown with common element numbers. Note that the interposer substrate 502C could be an organic interposer substrate or an inorganic interposer substrate, and could include one or more RDLs as discussed above for the interposer substrate 102.

With reference to FIG. 6C, the vias 352(1)(2), 352(2)(2) as a form of metal interconnects are inside the die cavity 362 in the first horizontal direction(s) (X-axis and/or Y-axis directions) like in the interposer substrate 502B in FIG. 6B. However, in this example, the lower surfaces 416 of the vias 352(1)(2) are recessed from the bottom surface 418 of the first metallization layer 336(1). This may be as a result of the etching or removal process to remove a metal portion of the vias 352(1)(2) in the first metallization layer 336(2). In this example, the lower surfaces 416 of the vias 352(1)(2) are still exposed to the die cavity 362 for improved thermal coupling.

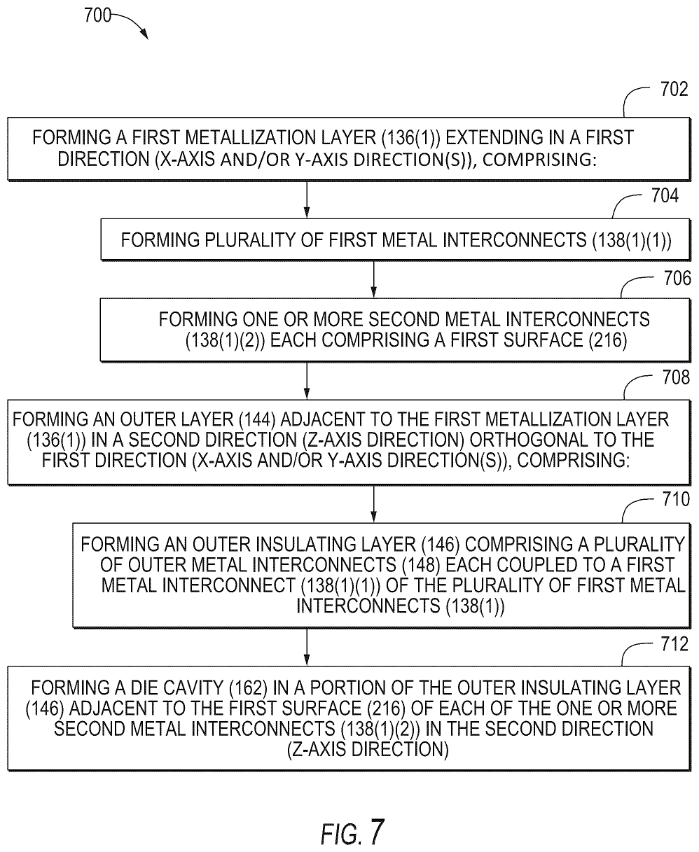

Interposer substrates that can be coupled to a die package, wherein an outer layer(s) of the interposer substrate includes an integrated die cavity to support extension of a die into the interposer substrate with metal interconnects in an outer metallization layer of the interposer substrate exposed to the die cavity for enhanced die heat dissipation, and/or with a reduced distance between the interposer substrate and the package substrate to support reduced aspect ratio vertical interconnects with a reduced pitch coupling the interposer substrate to the package substrate for signal routing, including, but not limited to, the interposer substrates in FIGS. 1A-6C, can be fabricated according to a fabrication process. In this regard, FIG. 7 is a flowchart illustrating an exemplary fabrication process 700 of fabricating an interposer substrate, including, but not limited to, the interposer substrates 102, 102A, 102B, 102C, 302, 302A, 302B, 302C, 502, 502A, 502B, 502C in FIGS. 1A-6C, that include an integrated die cavity to support extension of a die into the interposer substrate with metal interconnects in an outer metallization layer of the interposer substrate exposed to the die cavity for enhanced die heat dissipation, and/or with a reduced distance between the interposer substrate and the package substrate to support reduced aspect ratio vertical interconnects with a reduced pitch coupling the interposer substrate to the package substrate for signal routing. The fabrication process 700 in FIG. 7 is discussed in reference to the interposer substrates 102, 102A in FIGS. 1-2A, but such is not limiting and could be used to fabricate the interposer substrates 102B, 102C, 302, 302A, 302B, 302C, 502, 502A, 502B, 502C in FIGS. 2B-6C.

In this regard, as shown in FIG. 7, the fabrication process 700 of fabricating the interposer substrate 102 can include forming the first metallization layer 136(1) extending in a first direction (X-axis and/or Y-axis direction(s)) (block 702 in FIG. 7). Forming the first metallization layer 136(1) includes the plurality of first metal interconnects 138(1)(1) (block 704 in FIG. 7), and forming one or more second metal interconnects 138(1)(2) each comprising a first (bottom) surface 216 (block 706 in FIG. 7). The fabrication process 700 also includes forming an outer layer 144 adjacent to the first metallization layer 136(1) in a second direction (Z-axis direction) orthogonal to the first direction (X-axis and/or Y-axis direction(s)) (block 708 in FIG. 7). Forming the outer layer 144 includes forming an outer insulating layer 146 comprising a plurality of outer metal interconnects 148 each coupled to a first metal interconnect 138(1)(1) of the plurality of first metal interconnects 138(1)(1) (block 710 in FIG. 7). The fabrication process 700 also includes forming a die cavity 162 in at least a portion of the outer insulating layer 146 adjacent to the first (bottom) surface 216 of each of the one or more second metal interconnects 138(1)(2) in the second direction (Z-axis direction) (block 712 in FIG. 7).

An interposer substrate that can be coupled to a die package, wherein an outer layer(s) of the interposer substrate includes an integrated die cavity to support extension of a die into the interposer substrate with metal interconnects in an outer metallization layer of the interposer substrate exposed to the die cavity for enhanced die heat dissipation, and/or with a reduced distance between the interposer substrate and the package substrate to support reduced aspect ratio vertical interconnects with a reduced pitch coupling the interposer substrate to the package substrate for signal routing, including, but not limited to, the interposer substrates 102, 102A, 102B, 102C, 302, 302A, 302B, 302C, 502, 502A, 502B, 502C in FIGS. 1A-6C, can be fabricated in other fabrication processes.

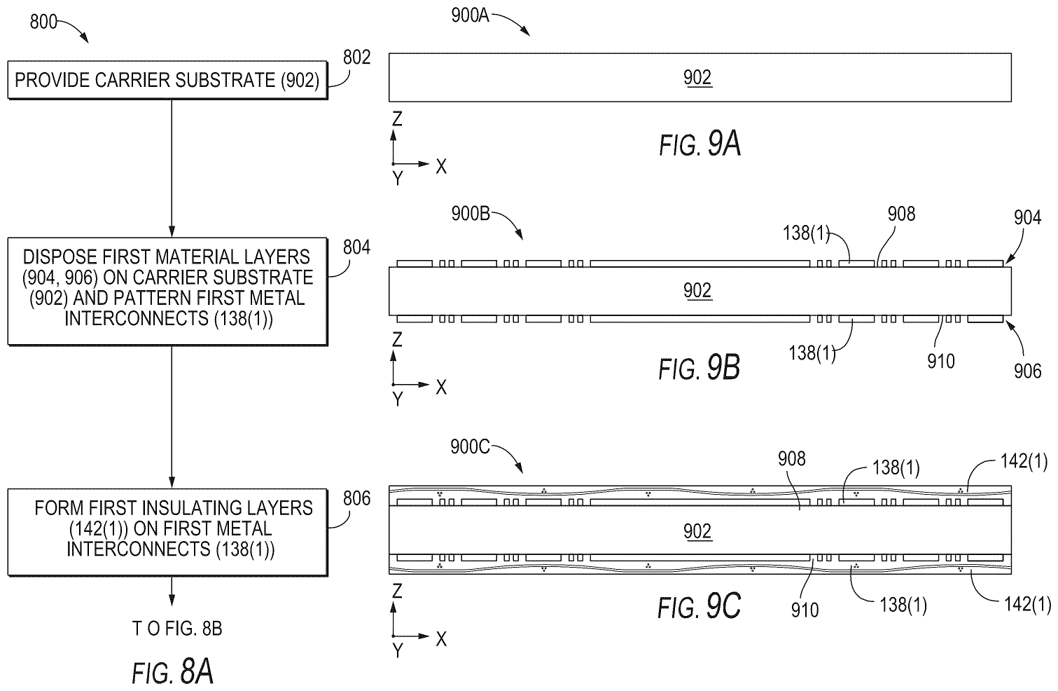

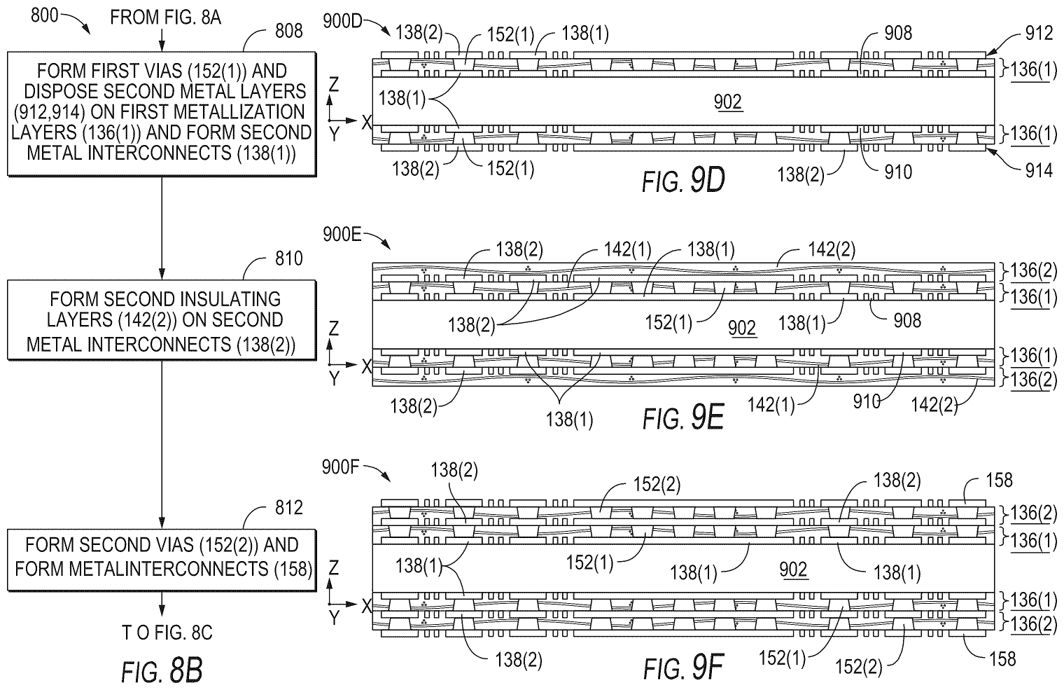

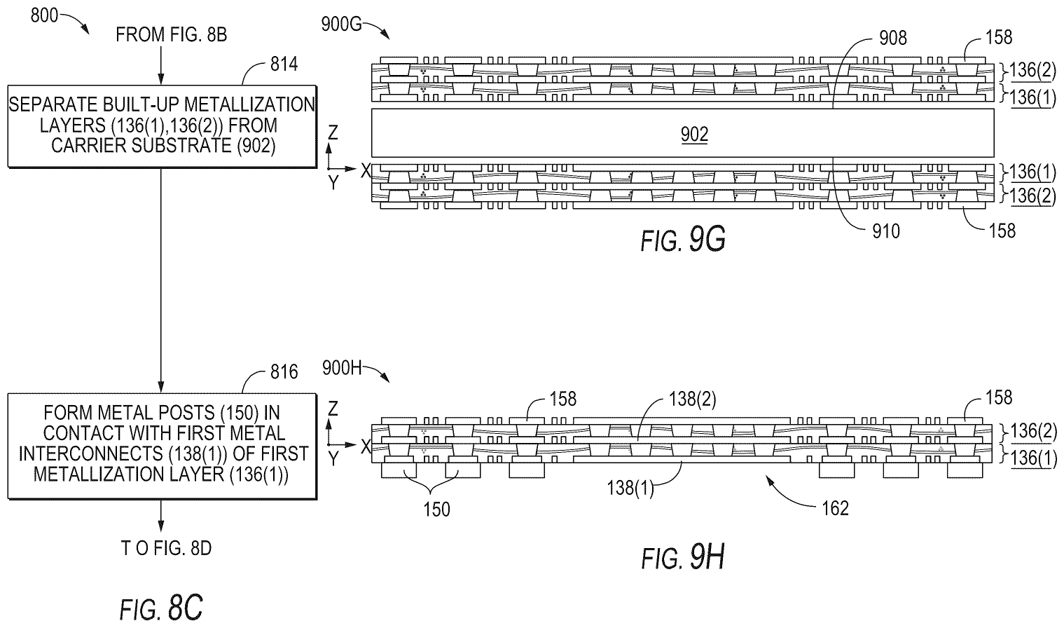

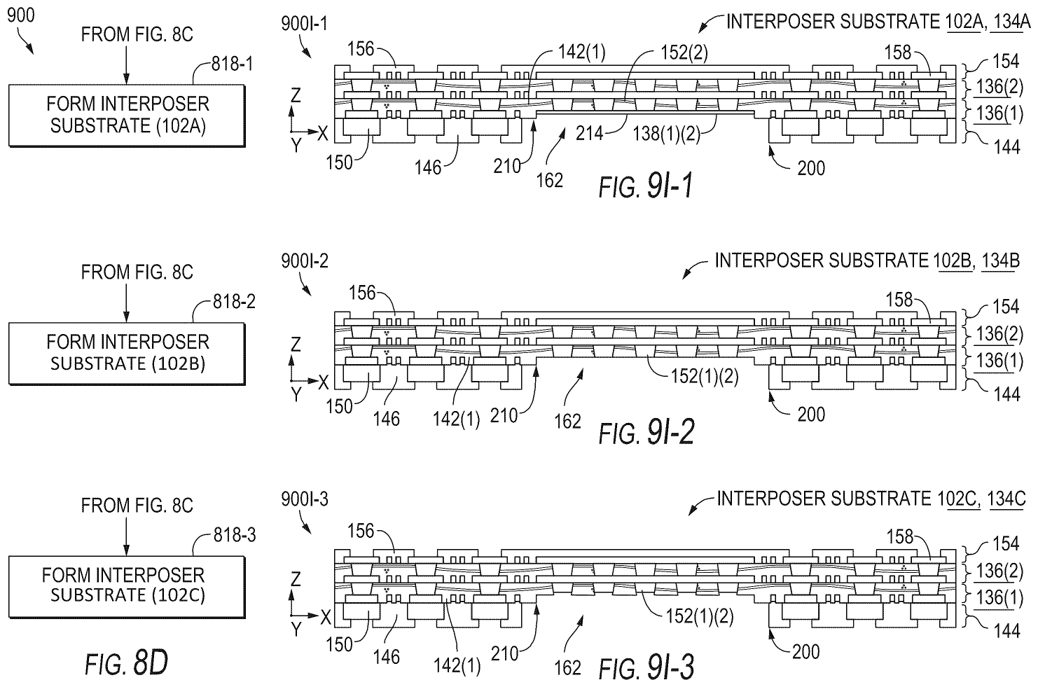

For example, FIGS. 8A-8D is a flowchart illustrating a fabrication process 800 of fabricating an interposer substrate that includes an integrated die cavity that can support extension of a die into the interposer substrate with metal interconnects in an outer metallization layer of the interposer substrate exposed to the die cavity for enhanced die heat dissipation, and/or with a reduced distance between the interposer substrate and the package substrate that can support reduced aspect ratio vertical interconnects with a reduced pitch coupling the interposer substrate to the package substrate for signal routing, including, but not limited to, the interposer substrates 102, 102A, 102B, 102C, 302, 302A, 302B, 302C, 502, 502A, 502B, 502C in FIGS. 1A-6C. FIGS. 9A-9I-3 are exemplary fabrication stages 900A-900I-3 during fabrication of interposer substrates according to the exemplary fabrication process 800 in FIGS. 8A-8D. The fabrication process 800 in FIGS. 8A-8D is discussed below with reference to the exemplary interposer substrate 102, 102A in FIGS. 1A-1B and 2A-2, but such is not limiting and could be used to fabricate the interposer substrates 102B, 102C, 302, 302A, 302B, 302C, 502, 502A, 502B, 502C in FIGS. 2B-6C.

In this regard, as shown in the exemplary fabrication stage 900A in FIG. 9A, a first step in the fabrication process 800 of the interposer substrate 102 can be to provide a carrier substrate 902 in which to build up metallization layers (block 802 in FIG. 8A). Then, as shown in the exemplary fabrication stage 900B in FIG. 9B, a next step in the fabrication process 800 is to dispose a first metal layer 904, 906 (e.g., a copper layer) on each respective side 908, 910 and then pattern metal interconnects 138(1) in the respective first metal layers 904, 906 as part of preparing metallization layers (block 804 in FIG. 8A). For example, after the first metal layers 904, 906 are disposed on the sides 908, 910 of the carrier substrate 902 as a continuous metal layer, a photoresist layer can be laminated over the first metal layers 904, 906, and then selectively exposed and developed to define a desired pattern of the first metal interconnects 138(1) that will be part of the first metallization layers 136(1). In this example, note that the process involves forming metallization layers for two (2) interposer substrates 102, which can then each be removed from the carrier substrate 902 to provide two (2) separate interposer substrates 102 for inclusion in an IC package. Then, as shown in the exemplary fabrication stage 900C in FIG. 9C, a next step in the fabrication process 800 is to form the first insulating layers 142(1) on the first metal interconnects 138(1) on each side 908, 910 of the carrier substrate 902 as part of the first metallization layers 136(1) (block 806 in FIG. 8A). For example, the insulating layers 142(1) may be a PPG material layer.

Then, as shown in the exemplary fabrication stage 900D in FIG. 9D, a next step in the fabrication process 800 is forming the first vias 152(1) in the first insulating layers 142(1) to form the first metallization layers 136(1) (block 808 in FIG. 8B). Second metal layers 912, 914 are then disposed on the first metallization layers 136(1) and then selectively exposed and developed to define a desired pattern of the second metal interconnects 138(2) that will be part of the second metallization layers 136(2). For example, after the second metal layers 912, 914 are disposed on the sides 908, 910 on the first metallization layers 136(1) as a continuous metal layer, a photoresist layer can be laminated over the second metal layers 912, 914, and then selectively exposed and developed to define a desired pattern of the second metal interconnects 138(2) that will be part of the second metallization layers 136(2). Then, as shown in the exemplary fabrication stage 900E in FIG. 9E, a next step in the fabrication process 800 is to form the second insulating layers 142(2) on the second metal interconnects 138(2) as part of the second metallization layers 136(2) (block 810 in FIG. 8B). For example, the second insulating layers 142(2) may be a PPG material layer. Then, as shown in the exemplary fabrication stage 900F in FIG. 9F, a next step in the fabrication process 800 is forming the second vias 152(2) in the second insulating layers 142(2) to form the second metallization layers 136(2) and to form metal interconnects 158 for what will become a solder resist layer (block 812 in FIG. 8B).

Then, as shown in the exemplary fabrication stage 900G in FIG. 9G, a next step in the fabrication process 800 is to separate the carrier substrate 902 from the built-up metallization layers 136(1), 136(2) on each side 908, 910 to provide separate structures to eventually provide two (2) separate interposer substrates 102 (block 814 in FIG. 8C). Then, as shown in the exemplary fabrication stage 900H in FIG. 9H, to prepare for the formation of the solder resist layer 144 and the formation of the die cavity 162, the metal posts 150 (e.g., copper posts) are formed in contact with the first metal interconnects 138(1) exposed from the first metallization layer 136(1) (block 816 in FIG. 8C). Also, as shown in fabrication stage 900H in FIG. 9H, the first metal interconnects 138(1)(2) inside the die cavity 162 in the first, horizontal directions (X-axis and/or Y-axis directions) can be etched to expose the first metal interconnects 138(1)(2) into the die cavity 162 for better thermal conductivity, as previously discussed with regard to the interposer substrate 102 in FIGS. 1A and 1B.

Then, as shown in the exemplary fabrication stages 900I-1, 900I-2, 900I-3 in respective FIGS. 9I-1, 9I-2, and 9I-3, which are mutually exclusive stages from fabrication stage 900H in FIG. 9H, the final interposer substrates 102A, 102B, 102C are formed (blocks 818-1, 818-2, and 818-3 in FIG. 8D). The final interposer substrates 102A, 102B, 102C are those shown and previously described in FIGS. 2A-1-2A-2, 2B, and 2C, respectively. As shown in FIGS. 9I-1-9I-3, part of forming the final interposer substrates 102A, 102B, 102C is to form the insulating layers on the metal interconnects 158 and metal posts 150 to form the respective solder resist layers 154, 144 on the respective second and first metallization layers 136(2), 136(1). As shown in FIG. 9I-1, the metal interconnect 138(1)(2) is the metal plate 214 as previously described in the interposer substrate 102A in FIGS. 2A-1 and 2A-2. The first insulating layer 142(1) of the first metallization layer 136(1) is also processed with material removed to expand the die cavity 162 into the first metallization layer 136(1) creating the second step structure 210. As shown in FIG. 9I-2, the metal interconnects 138(1)(2) are the vias 152(1)(2) as previously described in the interposer substrate 102B in FIG. 2B. The first insulating layer 142(1) of the first metallization layer 136(1) is also processed with material removed to expand the die cavity 162 into the first metallization layer 136(1) creating the second step structure 210. As shown in FIG. 9I-3, the metal interconnects 138(1)(2) are the vias 152(1)(2) as previously described in the interposer substrate 102B in FIG. 2B, but recessed into the first insulating layer 142(1). The first insulating layer 142(1) of the first metallization layer 136(1) is also processed with material removed to expand the die cavity 162 into the first metallization layer 136(1) creating the second step structure 210.

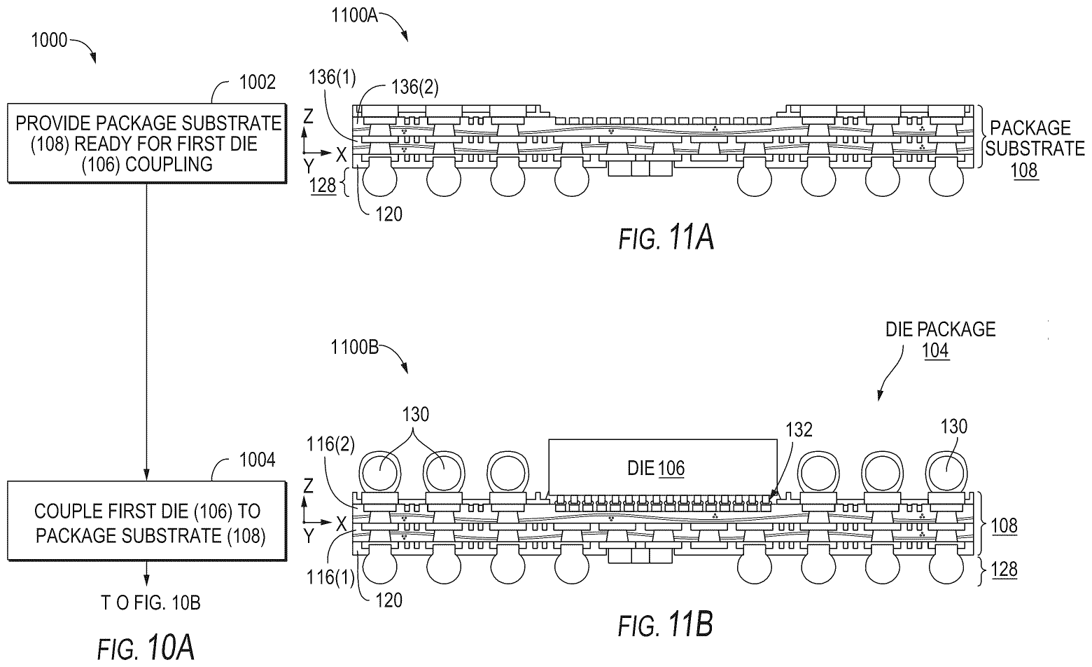

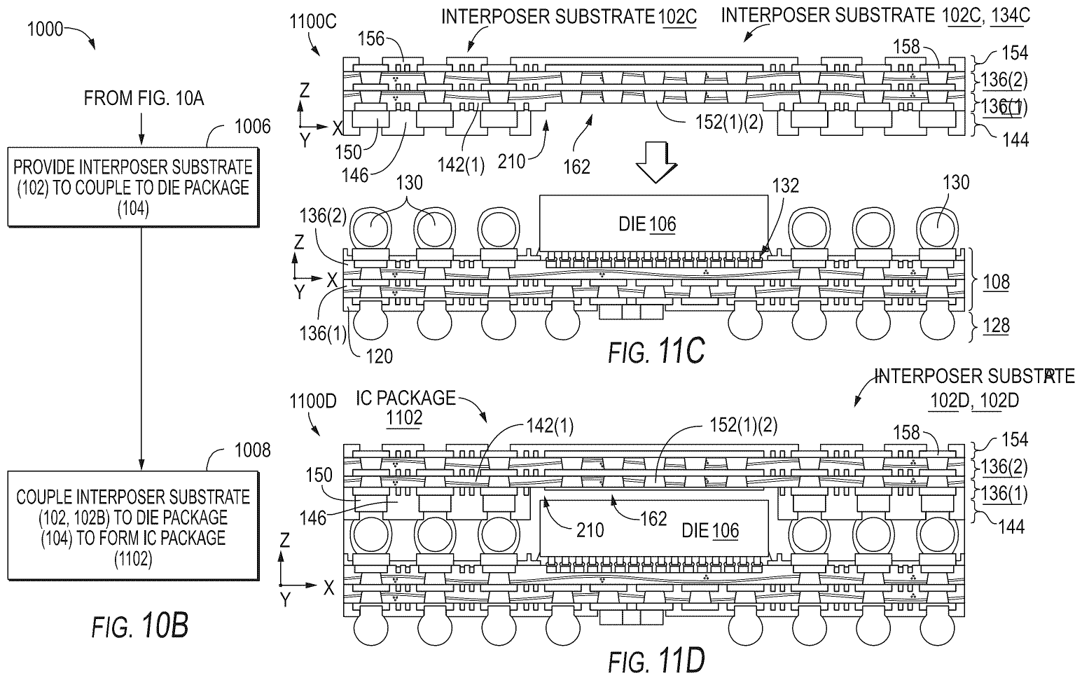

FIGS. 10A-10B is a flowchart illustrating a fabrication process 1000 of fabricating an IC package that includes an interposer substrate that includes an integrated die cavity that can support extension of a die into the interposer substrate with metal interconnects in an outer metallization layer of the interposer substrate exposed to the die cavity for enhanced die heat dissipation, and/or with a reduced distance between the interposer substrate and the package substrate that can support reduced aspect ratio vertical interconnects with a reduced pitch coupling the interposer substrate to the package substrate for signal routing, including, but not limited to, the interposer substrates 102, 102A, 102B, 102C, 302, 302A, 302B, 302C, 502, 502A, 502B, 502C in FIGS. 1A-6C. FIGS. 11A-11D are exemplary fabrication stages 1100A-1100D during fabrication of the IC package according to the exemplary fabrication process 1000 in FIGS. 10A-10B, and including, but not limited to, the IC packages 100, 300, 500 in FIGS. 1A-1B, 3A-3B, and 5A-5B.

In this regard, as shown in the exemplary fabrication stage 1100A in FIG. 11A, a first step in the fabrication process 1000 can be to provide the package substrate 108 ready for the first die 106 to be coupled (block 1002 in FIG. 10A). Then, as shown in the exemplary fabrication stage 1100B in FIG. 11B, a next step in the fabrication process 1000 can be to couple the first die 106 to the package substrate 108 to form the die package 104 (block 1004 in FIG. 10A). Then, as shown in the exemplary fabrication stage 1100C in FIG. 11C, a next step in the fabrication process 1000 is to provide the interposer substrate 102 to be coupled to the die package 104 to form an IC package 1102 (block 1006 in FIG. 10B). The first die 106 of the die package 104 is aligned with the die cavity 162 in the second, vertical direction (Z-axis direction), and the metal posts 150 are also aligned with the vertical interconnects 130 of the die package 104 in the second, vertical direction (Z-axis direction). Then, as shown in the exemplary fabrication stage 1100D in FIG. 11D, a next step in the fabrication process 1000 involves coupling the interposer substrate 102, 102B to the die package 104 to form the IC package 1102 (block 1008 in FIG. 10B). In this example, the interposer substrate 102 is the interposer substrate 102B in FIG. 2B, but such is not limiting.

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

IC packages with interposer substrates that include an integrated die cavity that can support extension of a die into the interposer substrate with metal interconnects in an outer metallization layer of the interposer substrate exposed to the die cavity for enhanced die heat dissipation, and/or with a reduced distance between the interposer substrate and the package substrate that can support reduced aspect ratio vertical interconnects with a reduced pitch coupling the interposer substrate to the package substrate for signal routing, one or more IC packages that includes an interposer substrate, wherein an outer layer(s) of the interposer substrate includes an integrated die cavity that can support extension of a die into the interposer substrate with metal interconnects in an outer metallization layer of the interposer substrate exposed to the die cavity for enhanced die heat dissipation, and/or with a reduced distance between the interposer substrate and the package substrate that can support reduced aspect ratio vertical interconnects with a reduced pitch coupling the interposer substrate to the package substrate for signal routing, including, but not limited to, the interposer substrates 102, 102A, 102B, 102C, 302, 302A, 302B, 302C, 502, 502A, 502B, 502C in FIGS. 1A-6C, 9I-1-9I-3, and 11D and the IC packages 100, 300, 500, 1102 in FIGS. 1A-1B, 3A-3B, 5A-5B, and 11D, and that can be fabricated according to a fabrication process, including, but not limited to, the exemplary fabrication processes 700, 800, 1000 in FIGS. 7, 8A-8D, and 10A-10B, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

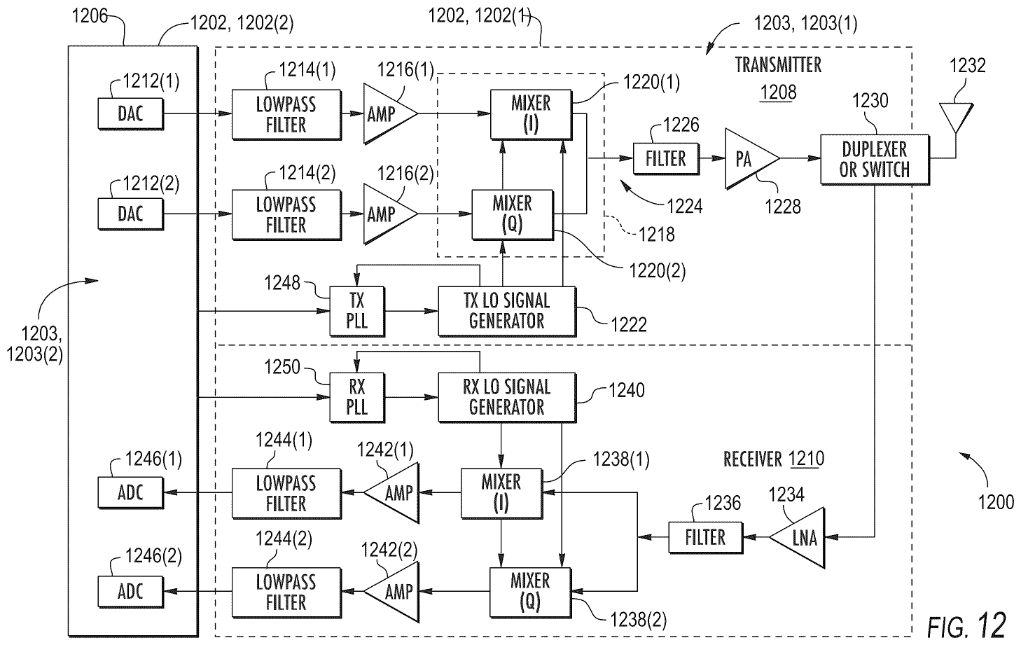

In this regard, FIG. 12 illustrates an exemplary wireless communications device 1200 that includes one or more IC packages 1202, 1202(1), 1202(2), including, but not limited to, the IC packages 100, 300, 500, 1102 in FIGS. 1A-1B, 3A-3B, 5A-5B, and 11D, that each include an interposer substrate 1203, 1203(1), 1203(2), including, but not limited to, the interposer substrates 102, 102A, 102B, 102C, 302, 302A, 302B, 302C, 502, 502A, 502B, 502C in FIGS. 1A-6C, 9I-1-9I-3, and 11D, that each include an interposer substrate that includes an integrated die cavity that can support extension of a die into the interposer substrate with metal interconnects in an outer metallization layer of the interposer substrate exposed to the die cavity for enhanced die heat dissipation, and/or with a reduced distance between the interposer substrate and the package substrate that can support reduced aspect ratio vertical interconnects with a reduced pitch coupling the interposer substrate to the package substrate for signal routing, one or more IC packages that includes an interposer substrate, wherein an outer layer(s) of the interposer substrate includes an integrated die cavity that can support extension of a die into the interposer substrate with metal interconnects in an outer metallization layer of the interposer substrate exposed to the die cavity for enhanced die heat dissipation, and/or with a reduced distance between the interposer substrate and the package substrate that can support reduced aspect ratio vertical interconnects with a reduced pitch coupling the interposer substrate to the package substrate for signal routing. The IC packages 1202, 1202(1), 1202(2) and their interposer substrates 1203, 1203(1), 1203(2) can be fabricated according to a fabrication process, including, but not limited to, the exemplary fabrication processes 700, 800, 1000 in FIGS. 7, 8A-8D, and 10A-10B, and according to any aspects disclosed herein.

The wireless communications device 1200 may include or be provided in any of the above-referenced devices, as examples. As shown in FIG. 12, the wireless communications device 1200 includes a transceiver 1204 and a data processor 1206. The data processor 1206 may include a memory to store data and program codes. The transceiver 1204 includes a transmitter 1208 and a receiver 1210 that support bi-directional communications. In general, the wireless communications device 1200 may include any number of transmitters 1208 and/or receivers 1210 for any number of communication systems and frequency bands. All or a portion of the transceiver 1204 may be implemented on one or more analog ICs, RF ICs (RFICs), mixed-signal ICs, etc.

The transmitter 1208 or the receiver 1210 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 1210. In the direct-conversion architecture, a signal is frequency-converted between RF and baseband in one stage. The super-heterodyne and direct-conversion architectures may use different circuit blocks and/or have different requirements. In the wireless communications device 1200 in FIG. 12, the transmitter 1208 and the receiver 1210 are implemented with the direct-conversion architecture.

In the transmit path, the data processor 1206 processes data to be transmitted and provides I and Q analog output signals to the transmitter 1208. In the exemplary wireless communications device 1200, the data processor 1206 includes digital-to-analog converters (DACs) 1212(1), 1212(2) for converting digital signals generated by the data processor 1206 into the I and Q analog output signals, e.g., I and Q output currents, for further processing.

Within the transmitter 1208, lowpass filters 1214(1), 1214(2) filter the I and Q analog output signals, respectively, to remove undesired signals caused by the prior digital-to-analog conversion. Amplifiers (AMPs) 1216(1), 1216(2) amplify the signals from the lowpass filters 1214(1), 1214(2), respectively, and provide I and Q baseband signals. An upconverter 1218 upconverts the I and Q baseband signals with I and Q transmit (TX) local oscillator (LO) signals through mixers 1220(1), 1220(2) from a TX LO signal generator 1222 to provide an upconverted signal 1224. A filter 1226 filters the upconverted signal 1224 to remove undesired signals caused by the frequency upconversion as well as noise in a receive frequency band. A power amplifier (PA) 1228 amplifies the upconverted signal 1224 from the filter 1226 to obtain the desired output power level and provides a transmit RF signal. The transmit RF signal is routed through a duplexer or switch 1230 and transmitted via an antenna 1232.

In the receive path, the antenna 1232 receives signals transmitted by base stations and provides a received RF signal, which is routed through the duplexer or switch 1230 and provided to a low noise amplifier (LNA) 1234. The duplexer or switch 1230 is designed to operate with a specific receive (RX)-to-TX duplexer frequency separation, such that RX signals are isolated from TX signals. The received RF signal is amplified by the LNA 1234 and filtered by a filter 1236 to obtain a desired RF input signal. Downconversion mixers 1238(1), 1238(2) mix the output of the filter 1236 with I and Q RX LO signals (i.e., LO_I and LO_Q) from an RX LO signal generator 1240 to generate I and Q baseband signals. The I and Q baseband signals are amplified by AMPs 1242(1), 1242(2) and further filtered by lowpass filters 1244(1), 1244(2) to obtain I and Q analog input signals, which are provided to the data processor 1206. In this example, the data processor 1206 includes analog-to-digital converters (ADCs) 1246(1), 1246(2) for converting the analog input signals into digital signals to be further processed by the data processor 1206.

In the wireless communications device 1200 of FIG. 12, the TX LO signal generator 1222 generates the I and Q TX LO signals used for frequency upconversion, while the RX LO signal generator 1240 generates the I and Q RX LO signals used for frequency downconversion. Each LO signal is a periodic signal with a particular fundamental frequency. A TX phase-locked loop (PLL) circuit 1248 receives timing information from the data processor 1206 and generates a control signal used to adjust the frequency and/or phase of the TX LO signals from the TX LO signal generator 1222. Similarly, an RX PLL circuit 1250 receives timing information from the data processor 1206 and generates a control signal used to adjust the frequency and/or phase of the RX LO signals from the RX LO signal generator 1240.

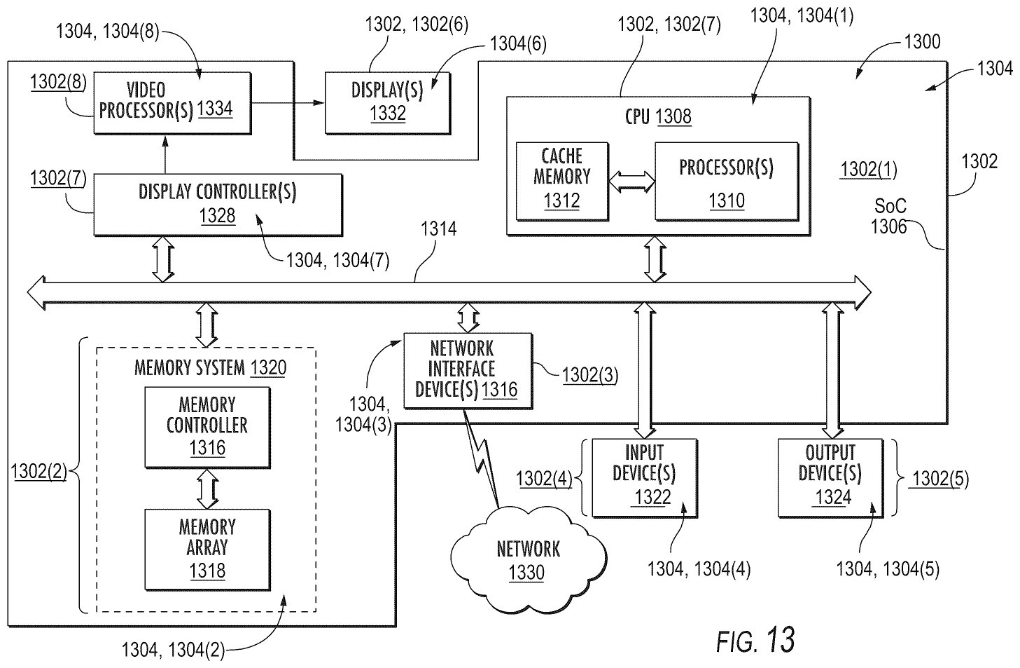

FIG. 13 illustrates an example of a processor-based system 1300 that includes one or more IC packages 1302, 1302(1)-1302(8), including, but not limited to, the IC packages 100, 300, 500, 1102 in FIGS. 1A-1B, 3A-3B, 5A-5B, and 11D, that each include an interposer substrate 1304, 1304(1)-1304(8), including, but not limited to, the interposer substrates 102, 102A, 102B, 102C, 302, 302A, 302B, 302C, 502, 502A, 502B, 502C in FIGS. 1A-6C, 9I-1-9I-3, and 11D, that includes an integrated die cavity that can support extension of a die into the interposer substrate with metal interconnects in an outer metallization layer of the interposer substrate exposed to the die cavity for enhanced die heat dissipation, and/or with a reduced distance between the interposer substrate and the package substrate that can support reduced aspect ratio vertical interconnects with a reduced pitch coupling the interposer substrate to the package substrate for signal routing, one or more IC packages that includes an interposer substrate, wherein an outer layer(s) of the interposer substrate includes an integrated die cavity that can support extension of a die into the interposer substrate with metal interconnects in an outer metallization layer of the interposer substrate exposed to the die cavity for enhanced die heat dissipation, and/or with a reduced distance between the interposer substrate and the package substrate that can support reduced aspect ratio vertical interconnects with a reduced pitch coupling the interposer substrate to the package substrate for signal routing. The IC packages 1302, 1302(1)-1302(8) and their interposer substrates 1304, 1304(1)-1304(8) can be fabricated according to a fabrication process, including, but not limited to, the exemplary fabrication processes 700, 800, 1000 in FIGS. 7, 8A-8D, and 10A-10B, and according to any aspects disclosed herein.

In this example, the processor-based system 1300 may include an interposer substrate 1304 that is included in an IC package 1302, such as a system-on-a-chip (SoC) 1306. The processor-based system 1300 includes a CPU 1308 that includes one or more processors 1310, which may also be referred to as CPU cores or processor cores. The CPU 1308 can be provided in an IC package 1302(1) that includes the interposer substrate 1304(1). The CPU 1308 may have cache memory 1312 coupled to the CPU 1308 for rapid access to temporarily stored data. The CPU 1308 is coupled to a system bus 1314 and can intercouple master and slave devices included in the processor-based system 1300. As is well known, the CPU 1308 communicates with these other devices by exchanging address, control, and data information over the system bus 1314. For example, the CPU 1308 can communicate bus transaction requests to a memory controller 1316 as an example of a slave device. Although not illustrated in FIG. 13, multiple system buses 1314 could be provided, wherein each system bus 1314 constitutes a different fabric.

Other master and slave devices can be connected to the system bus 1314. As illustrated in FIG. 13, these devices can include a memory system 1320 that includes the memory controller 1316 and a memory array(s) 1318, one or more input devices 1322, one or more output devices 1324, one or more network interface devices 1326, and one or more display controllers 1328, as examples. The memory system 1320 can be provided in an IC package 1302(2) that includes the interposer substrate 1304(2). The network interface devices 1326 can be provided in an IC package 1302(3) that includes the interposer substrate 1304(3). Each of the memory system 1320, the one or more input devices 1322, the one or more output devices 1324, the one or more network interface devices 1326, and the one or more display controllers 1328 can be provided in the same or different circuit packages. The input devices 1322 and/or the output devices 1324 can be provided in a respective IC package 1302(4), 1302(5) that includes a respective interposer substrate 1304(4), 1304(5). The input device(s) 1322 can include any type of input device, including, but not limited to, input keys, switches, voice processors, etc. The output device(s) 1324 can include any type of output device, including, but not limited to, audio, video, other visual indicators, etc. The network interface device(s) 1326 can be any device configured to allow exchange of data to and from a network 1330. The network 1330 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1326 can be configured to support any type of communications protocol desired.

The CPU 1308 may also be configured to access the display controller(s) 1328 over the system bus 1314 to control information sent to one or more displays 1332. The display 1332 can be provided in an IC package 1302(6) that includes the interposer substrate 1304(6). The display controller(s) 1328 sends information to the display(s) 1332 to be displayed via one or more video processors 1334, which process the information to be displayed into a format suitable for the display(s) 1332. The display controller(s) 1328 and video processor(s) 1334 can be provided in a respective IC package 1302(7), 1302(8) that includes the interposer substrate 1304(7), 1304(8), or be provided in the same IC package 1302, or be provided in the same IC package 1302(1) containing the CPU 1308 as an example. The display(s) 1332 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An interposer substrate, comprising:
   a first metallization layer extending in a first direction, the first metallization layer comprising:
      a plurality of first metal interconnects; and
      one or more second metal interconnects each comprising a first surface;
   an outer layer adjacent to the first metallization layer in a second direction orthogonal to the first direction, the outer layer comprising:
      an outer insulating layer comprising a plurality of outer metal interconnects each coupled to a first metal interconnect of the plurality of first metal interconnects; and
   a die cavity in at least a portion of the outer insulating layer adjacent to a first surface of each of the one or more second metal interconnects in the second direction.
2. The interposer substrate of clause 1, wherein at least a portion of the first surface of the one or more second metal interconnects is exposed to the die cavity.
3. The interposer substrate of clause 1 or 2, wherein the one or more second metal interconnects comprise a metal plate.
4. The interposer substrate of clause 1 or 2, wherein:
   the first metallization layer comprises a third surface and a fourth surface opposite the third surface in the second direction,
      the third surface adjacent to the die cavity and intersecting the die cavity in the second direction; and
   the first surface of the one or more second metal interconnects are co-planar with the fourth surface in the first direction.
5. The interposer substrate of clause 1 or 2, wherein:
   the first metallization layer comprises a third surface and a fourth surface opposite the third surface in the second direction,
      the third surface adjacent to the die cavity and intersecting the die cavity in the second direction; and
   the first surface of the one or more second metal interconnects are recessed into the first metallization layer from the fourth surface in the first direction.
6. The interposer substrate of any of clauses 1-5, wherein:
   the outer layer comprises a solder resist layer;
   the plurality of outer metal interconnects comprises a plurality of metal posts; and
   the solder resist layer comprises a plurality of first openings each adjacent to a metal post of the plurality of metal posts.
7. The interposer substrate of clause 6, wherein the plurality of metal posts do not intersect the die cavity in the second direction.
8. The interposer substrate of any of clauses 1-7, wherein the plurality of first metal interconnects do not intersect the die cavity in the second direction.
9. The interposer substrate of any of clauses 1-8, wherein the one or more second metal interconnects at least partially intersect the die cavity in the second direction.
10. The interposer substrate of any of clauses 1-9, further comprising a second metallization layer adjacent to the first metallization layer in the first direction,
   wherein:
      the first metallization layer is between the outer layer and the second metallization layer in the first direction; and
      the second metallization layer comprises a plurality of third metal interconnects each coupled to a first metal interconnect of the plurality of first metal interconnects.
11. The interposer substrate of any of clauses 1-10, wherein the first metallization layer comprises an embedded trace substrate (ETS) metallization layer comprising a first insulating layer,
   the plurality of first metal interconnects comprising a plurality of first metal traces embedded in the first insulating layer.
12. The interposer substrate of clause 11, wherein the one or more second metal interconnects comprise a plurality of second vias.
13. The interposer substrate of clause 11 or 12, wherein:
   the first insulating layer further comprises:
      a non-recessed layer portion comprising the plurality of first metal traces and having a first height in the second direction; and
      a recessed layer portion comprising the one or more second metal interconnects and forming a recessed region adjacent to the first surface of the one or more second metal interconnects, the recessed layer portion having a second height in the second direction less than the first height; and
   the die cavity further comprising the recessed region.
14. The interposer substrate of clause 13, wherein the first insulating layer comprises a step structure formed in a first portion of the non-recessed layer portion adjacent to a second portion of the recessed layer portion in the first direction.
15. The interposer substrate of clause 14, wherein the die cavity is adjacent to the step structure.
16. The interposer substrate of any of clauses 1-10, wherein the first metallization layer comprises a modified semi-additive process (mSAP) metallization layer comprising a first insulating layer,
   the plurality of first metal interconnects adjacent to the first insulating layer.
17. The interposer substrate of clause 16, wherein the one or more second metal interconnects comprise a plurality of second vias.
18. The interposer substrate of clause 16 or 17, wherein:
   the first insulating layer comprises:
      a first layer portion having a first height in the second direction and adjacent to the plurality of first metal interconnects in the second direction; and
      a second layer portion having the first height in the second direction and adjacent to the one or more second metal interconnects in the second direction.
19. The interposer substrate of any of clauses 16-18 not comprising a core layer.
20 The interposer substrate of any of clauses 16-18, further comprising a core layer adjacent to the first metallization layer;
   wherein the first metallization layer is between the core layer and the outer layer in the second direction.
21. The interposer substrate of any of clauses 1-20 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
22. A method of fabricating an interposer substrate for an integrated circuit (IC) package, comprising:
   forming a first metallization layer extending in a first direction, comprising:
      forming a plurality of first metal interconnects; and
      forming one or more second metal interconnects each comprising a first surface;
   forming an outer layer adjacent to the first metallization layer in a second direction orthogonal to the first direction, comprising:
      forming an outer insulating layer comprising a plurality of outer metal interconnects each coupled to a first metal interconnect of the plurality of first metal interconnects; and
   forming a die cavity in at least a portion of the outer insulating layer adjacent to a first surface of each of the one or more second metal interconnects in the second direction.
23. The method of clause 22, wherein forming the die cavity further comprises at least partially exposing the first surface of the one or more second metal interconnects.
24. The method of clause 22 or 23, wherein forming the one or more second metal interconnects comprises forming a metal plate.
25. The method of clause 22 or 23, wherein forming the one or more second metal interconnects comprises forming the one or more second metal interconnects co-planar with a third surface of the first metallization layer adjacent to the die cavity and intersecting the die cavity the second direction.
26. The method of clause 22 or 23, wherein forming the one or more second metal interconnects comprises forming the one or more second metal interconnects recessed from a third surface of the first metallization layer adjacent to the die cavity and intersecting the die cavity the second direction.
27. The method of any of clauses 22-26, wherein forming the die cavity further comprises removing the portion of the outer insulating layer from the outer layer adjacent to the one or more second metal interconnects.
28. The method of clause 27, wherein forming the die cavity further comprises removing a portion of a first insulating layer from the first metallization layer adjacent to the one or more second interconnects.
29 An integrated circuit (IC) package, comprising:
   a die package, comprising:
      a package substrate comprising a plurality of fourth metal interconnects;
      a first die coupled to the package substrate; and
      a plurality of vertical interconnects each coupled to a fourth metal interconnect of the plurality of fourth metal interconnects; and
   an interposer substrate coupled to the die package in a second direction orthogonal to a first direction, the interposer substrate comprising:
      a first metallization layer extending in the first direction, the first metallization layer comprising:
         a plurality of first metal interconnects; and
         one or more second metal interconnects each comprising a first surface;
      an outer layer coupled to the die package and between the die package and the first metallization layer in the second direction, the outer layer comprising:
         an outer insulating layer comprising a plurality of outer metal interconnects each coupled to a first metal interconnect of the plurality of first metal interconnects and a vertical interconnect of the plurality of vertical interconnects; and
      a die cavity in at least a portion of the outer insulating layer adjacent to a first surface of each of the one or more second metal interconnects in the second direction;
   the first die at least partially disposed in the die cavity in the second direction.
30. The IC package of clause 29, wherein the die package further comprises a mold layer adjacent to a second surface of the package substrate and the first die;
   wherein:
      the interposer substrate is coupled to the mold layer, and
      the plurality of vertical interconnects are disposed in the mold layer.

What is claimed is:

1. An interposer substrate, comprising:
a first metallization layer extending in a first direction, the first metallization layer comprising:
a plurality of first metal interconnects; and
one or more second metal interconnects each comprising a first surface;
an outer layer adjacent to the first metallization layer in a second direction orthogonal to the first direction, the outer layer comprising:
an outer insulating layer comprising a plurality of outer metal interconnects each coupled to a first metal interconnect of the plurality of first metal interconnects; and
a die cavity in at least a portion of the outer insulating layer adjacent to a first surface of each of the one or more second metal interconnects in the second direction.

2. The interposer substrate of claim 1, wherein at least a portion of the first surface of the one or more second metal interconnects is exposed to the die cavity.

3. The interposer substrate of claim 1, wherein the one or more second metal interconnects comprise a metal plate.

4. The interposer substrate of claim 1, wherein:
the first metallization layer comprises a third surface and a fourth surface opposite the third surface in the second direction,
the third surface adjacent to the die cavity and intersecting the die cavity in the second direction; and
the first surface of the one or more second metal interconnects are co-planar with the fourth surface in the first direction.

5. The interposer substrate of claim 1, wherein:
the first metallization layer comprises a third surface and a fourth surface opposite the third surface in the second direction,
the third surface adjacent to the die cavity and intersecting the die cavity in the second direction; and
the first surface of the one or more second metal interconnects are recessed into the first metallization layer from the fourth surface in the first direction.

6. The interposer substrate of claim 1, wherein:
the outer layer comprises a solder resist layer;
the plurality of outer metal interconnects comprises a plurality of metal posts; and
the solder resist layer comprises a plurality of first openings each adjacent to a metal post of the plurality of metal posts.

7. The interposer substrate of claim 6, wherein the plurality of metal posts do not intersect the die cavity in the second direction.

8. The interposer substrate of claim 1, wherein the plurality of first metal interconnects do not intersect the die cavity in the second direction.

9. The interposer substrate of claim 1, wherein the one or more second metal interconnects at least partially intersect the die cavity in the second direction.

10. The interposer substrate of claim 1, further comprising a second metallization layer adjacent to the first metallization layer in the first direction,
wherein:
the first metallization layer is between the outer layer and the second metallization layer in the first direction; and
the second metallization layer comprises a plurality of third metal interconnects each coupled to a first metal interconnect of the plurality of first metal interconnects.

11. The interposer substrate of claim 1, wherein the first metallization layer comprises an embedded trace substrate (ETS) metallization layer comprising a first insulating layer,
the plurality of first metal interconnects comprising a plurality of first metal traces embedded in the first insulating layer.

12. The interposer substrate of claim 11, wherein the one or more second metal interconnects comprise a plurality of second vias.

13. The interposer substrate of claim 11, wherein:
the first insulating layer further comprises:
a non-recessed layer portion comprising the plurality of first metal traces and having a first height in the second direction; and
a recessed layer portion comprising the one or more second metal interconnects and forming a recessed region adjacent to the first surface of the one or more second metal interconnects, the recessed layer portion having a second height in the second direction less than the first height; and
the die cavity further comprising the recessed region.

14. The interposer substrate of claim 13, wherein the first insulating layer comprises a step structure formed in a first portion of the non-recessed layer portion adjacent to a second portion of the recessed layer portion in the first direction.

15. The interposer substrate of claim 14, wherein the die cavity is adjacent to the step structure.

16. The interposer substrate of claim 1, wherein the first metallization layer comprises a modified semi-additive process (mSAP) metallization layer comprising a first insulating layer,
the plurality of first metal interconnects adjacent to the first insulating layer.

17. The interposer substrate of claim 16, wherein the one or more second metal interconnects comprise a plurality of second vias.

18. The interposer substrate of claim 16, wherein:
the first insulating layer comprises:
a first layer portion having a first height in the second direction and adjacent to the plurality of first metal interconnects in the second direction; and
a second layer portion having the first height in the second direction and adjacent to the one or more second metal interconnects in the second direction.

19. The interposer substrate of claim 16 not comprising a core layer.

20. The interposer substrate of claim 16, further comprising a core layer adjacent to the first metallization layer;
wherein the first metallization layer is between the core layer and the outer layer in the second direction.

21. The interposer substrate of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

22. A method of fabricating an interposer substrate for an integrated circuit (IC) package, comprising:
forming a first metallization layer extending in a first direction, comprising:
forming a plurality of first metal interconnects; and
forming one or more second metal interconnects each comprising a first surface;
forming an outer layer adjacent to the first metallization layer in a second direction orthogonal to the first direction, comprising:
forming an outer insulating layer comprising a plurality of outer metal interconnects each coupled to a first metal interconnect of the plurality of first metal interconnects; and
forming a die cavity in at least a portion of the outer insulating layer adjacent to a first surface of each of the one or more second metal interconnects in the second direction.

23. The method of claim 22, wherein forming the die cavity further comprises at least partially exposing the first surface of the one or more second metal interconnects.

24. The method of claim 22, wherein forming the one or more second metal interconnects comprises forming a metal plate.

25. The method of claim 22, wherein forming the one or more second metal interconnects comprises forming the one or more second metal interconnects co-planar with a third surface of the first metallization layer adjacent to the die cavity and intersecting the die cavity the second direction.

26. The method of claim 22, wherein forming the one or more second metal interconnects comprises forming the one or more second metal interconnects recessed from a third surface of the first metallization layer adjacent to the die cavity and intersecting the die cavity the second direction.

27. The method of claim 22, wherein forming the die cavity further comprises removing the portion of the outer insulating layer from the outer layer adjacent to the one or more second metal interconnects.

28. The method of claim 27, wherein forming the die cavity further comprises removing a portion of a first insulating layer from the first metallization layer adjacent to the one or more second interconnects.

29. An integrated circuit (IC) package, comprising:
a die package, comprising:
a package substrate comprising a plurality of fourth metal interconnects;
a first die coupled to the package substrate; and
a plurality of vertical interconnects each coupled to a fourth metal interconnect of the plurality of fourth metal interconnects; and
an interposer substrate coupled to the die package in a second direction orthogonal to a first direction, the interposer substrate comprising:
a first metallization layer extending in the first direction, the first metallization layer comprising:
a plurality of first metal interconnects; and
one or more second metal interconnects each comprising a first surface;
an outer layer coupled to the die package and between the die package and the first metallization layer in the second direction, the outer layer comprising:
an outer insulating layer comprising a plurality of outer metal interconnects each coupled to a first metal interconnect of the plurality of first metal interconnects and a vertical interconnect of the plurality of vertical interconnects; and
a die cavity in at least a portion of the outer insulating layer adjacent to a first surface of each of the one or more second metal interconnects in the second direction;
the first die at least partially disposed in the die cavity in the second direction.

30. The IC package of claim 29, wherein the die package further comprises a mold layer adjacent to a second surface of the package substrate and the first die;
wherein:
the interposer substrate is coupled to the mold layer; and
the plurality of vertical interconnects are disposed in the mold layer.
